(19) United States
(12) Patent Application Publication
(10) Pub. No.: US 2014/0030600 A1
(43) Pub. Date: Jan. 30, 2014

(54) GRAPHENE SHEET, TRANSPARENT ELECTRODE AND ACTIVE LAYER INCLUDING THE SAME, AND DISPLAY, ELECTRONIC DEVICE, OPTOELECTRONIC DEVICE, BATTERY, SOLAR CELL, AND DYE-SENSITIZED SOLAR CELL INCLUDING TRANSPARENT ELECTRODE OR ACTIVE LAYER

(71) Applicant: UNIST Academy-Industry Research Corporation, Ulsan (KR)

(72) Inventors: Soon-Yong Kwon, Ulsan (KR); Kibog Park, Ulsan (KR); Sung Youb Kim, Ulsan (KR); Jin-Sung Kwak, Busan (KR)

(73) Assignee: UNIST Academy-Industry Research Corporation, Ulsan (KR)

(21) Appl. No.: 14/037,590

(22) Filed: Sep. 26, 2013

Related U.S. Application Data
(63) Continuation of application No. PCT/KR2012/002269, filed on Mar. 28, 2012.

(30) Foreign Application Priority Data
Mar. 9, 2011 (KR) 10-2011-0028463

(51) Int. Cl. H01L 33/04; H01M 4/583; H01B 1/04

(52) U.S. Cl. CPC H01L 33/04; H01B 1/04; H01M 4/583; Y10S 977/734; Y10S 977/95; B82Y 20/00
USPC 429/231.8; 257/13; 428/195.1; 428/1.4; 977/734; 977/950

(57) ABSTRACT

A graphene sheet including a lower sheet including 1 to 20 layers of graphene, and a ridge formed on the lower sheet and including more layers of the graphene compared with the lower sheet, the ridge having a shape of a grain boundary of a metal, a transparent electrode and an active layer including the same, and a display, an electronic device, an optoelectronic device, a battery, a solar cell, and a dye-sensitized solar cell including the transparent electrode and/or the active layer are provided.

### CROSS-REFERENCE TO RELATED APPLICATION

This application is a continuation application of International Application No. PCT/KR2012/002269 filed on Mar. 28, 2012, which claims priority to Korean Patent Application No. 10-2011-0028463, filed on Mar. 29, 2011, the entire contents of which are incorporated herein by reference.

### BACKGROUND OF THE INVENTION

(a) Field of the Invention

The present invention relates to a graphene sheet, a transparent electrode and an active layer including the same, and a display, an electronic device, an optoelectronic device, a battery, a solar cell, and a dye-sensitized solar cell including the transparent electrode and/or the active layer.

(b) Description of the Related Art

In general, since various devices such as a display, a light emitting diode, a solar cell, and the like transmit light to display an image or to produce electric power, the devices are used as a constituent element necessarily requiring a transparent electrode transmitting light. Indium tin oxide (ITO) is the most well-known material for forming the transparent electrode and is widely used.

However, indium tin oxide is problematic in that its cost is increased as consumption of indium is increased, and thus economic efficiency is reduced. Indium deposits of the earth have been depleted, and particularly, a transparent electrode using indium as a material conventionally has chemical and electrical characteristic defects. Accordingly, active attempts to find an electrode material that can replace indium tin oxide are being conducted.

In addition, for an electronic device and a semiconductor device, silicon is generally used as an active layer. A thin film transistor will be described as a specific example.

A general thin film transistor is constituted by multilayers, and includes a semiconductor layer, an insulating layer, a passivation layer, and an electrode layer. Each layer constituting the thin film transistor is formed by forming a film by a sputtering method or a chemical vapor deposition (CVD) method, and then appropriately patterning the film through a lithography technology. Currently, a widely used thin film transistor has an amorphous silicon layer as a semiconductor layer as a conductive channel through which electrons flow. However, there is a limit in a display due to low electron mobility of the amorphous silicon layer.

Silicon has carrier mobility of about 1000 cm²/Vs at room temperature.

In order to solve the problem, in Japanese Patent Laid-Open Publication No. Hei. 11-340473, when the thin film transistor is manufactured, the passivation layer and the amorphous silicon layer are sequentially applied on a substrate, and then crystallized by a laser to form a polysilicon layer as the active layer. In this method, application of the passivation layer and the amorphous silicon layer is performed by high frequency (RF, radio frequency) sputtering. However, RF sputtering has drawbacks in that since application speed is very slow and a thickness is non-uniform, a layer sensitive to a change in density of laser energy is formed, and thus the polysilicon layer having an unstable electrical characteristic is formed when crystallization is performed by the laser.

Meanwhile, in addition to sputtering, the chemical vapor deposition method may be used to form the passivation layer and the polysilicon active layer. In this case, a process temperature reaches 500° C., and thus a glass substrate should be annealed at high temperatures and then used. Further, hydrogen causing a problem that is fatal to the film when crystallization is performed by the laser is mixed and included in the thin film, and thus an annealing process of removing hydrogen is additionally required, and it is difficult to form the polysilicon layer having a uniform electrical characteristic.

Accordingly, a novel material that can replace silicon needs to be used in order to manufacture a faster and better device.

The above information disclosed in this Background section is only for enhancement of understanding of the background of the invention and therefore it may contain information that does not form the prior art that is already conventional in this country to a person of ordinary skill in the art.

### SUMMARY OF THE INVENTION

An exemplary embodiment of the present invention provides a graphene sheet having a large area and/or a graphene sheet having excellent electrical and optical characteristics.

Another embodiment of the present invention provides a transparent electrode including the graphene sheet and having improved chemical, electrical, and optical characteristics.

Yet another embodiment of the present invention provides an active layer for an organic/inorganic electronic device, which includes the graphene sheet and has improved physical, electrical, and optical characteristics.

Still another embodiment of the present invention provides a display, an organic/inorganic optoelectronic/electronic device, a battery, a solar cell, or a dye-sensitized solar cell including the transparent electrode and the active layer.

According to one aspect of the present invention, a graphene sheet is provided, which includes a lower sheet including 1 to 20 layers of graphene, and a ridge formed on the lower sheet and including more layers of the graphene compared with the lower sheet. The ridge may have a shape of a grain boundary of a metal.

The ridge may include 3 to 50 layers of the graphene.

A size of a metal grain may be 10 nm to 10 mm.

The size of the metal grain may be 10 nm to 500 μm.

The size of the metal grain may be 50 nm to 10 μm.

The lower sheet may be a flat sheet.

The metal may include Ni, Co, Fe, Pt, Au, Al, Cr, Cu, Mg, Mn, Mo, Rh, Si, Ta, Ti, W, U, V, Zr, Zn, Sr, Y, Nb, Tc, Ru, Pd, Ag, Cd, In, Re, Os, Ir, Pb, or a combination thereof.

Light transmittance of the graphene sheet may be 60% or more.

The light transmittance of the graphene sheet may be 80% or more.

Sheet resistance of the graphene sheet may be 2000 Ω/square or less.

The sheet resistance of the graphene sheet may be 274 Ω/square or less.

The sheet resistance of the graphene sheet may be 100 Ω/square or less.

According to another aspect of the present invention, a transparent electrode including the graphene sheet is provided.

According to yet another aspect of the present invention, an active layer including the graphene sheet is provided.

According to still another aspect of the present invention, a display including the transparent electrode is provided.

According to still another aspect of the present invention, an electronic device including the active layer is provided.

The display may be a liquid crystal display, an electronic paper display, or an optoelectronic device.

The electronic device may be a transistor, a sensor, or an organic/inorganic semiconductor device.

According to still another aspect of the present invention, an optoelectronic device including an anode, a hole transport layer, an emission layer, an electron transport layer, and a cathode is provided. The anode may be the aforementioned transparent electrode.

The optoelectronic device may further include an electron injection layer and a hole injection layer.

According to still another aspect of the present invention, a battery including the transparent electrode is provided.

According to still another aspect of the present invention, a solar cell including the transparent electrode is provided.

According to still another aspect of the present invention, a solar cell including at least one active layer between lower and upper electrode layers laminated on a substrate is provided. The active layer may be the aforementioned active layer.

According to still another aspect of the present invention, a dye-sensitized solar cell is provided, which includes a semiconductor electrode, an electrolyte layer, and an opposed electrode. The semiconductor electrode includes a transparent electrode and a photoabsorption layer, the photoabsorption layer includes a nanoparticle oxide and a dye, and the transparent electrode and the opposed electrode may be the aforementioned transparent electrode.

The graphene sheet having a large area may be supplied on a subject substrate without a transfer process.

Further, the graphene sheet having excellent electrical and optical characteristics may be provided.

A display, an optoelectronic/electronic device, a battery, and a solar cell having excellent chemical, electrical, and optical characteristics, and a transistor, a sensor, and an organic/inorganic semiconductor device having excellent physical, electrical, and optical characteristics, may be fabricated by using the graphene sheet.

### BRIEF DESCRIPTION OF THE DRAWINGS

FIG. 1 is a top plan view of a graphene sheet according to one embodiment of the present invention.

FIG. 2 is a cross-sectional view of the graphene sheet according to one embodiment of the present invention.

FIG. 3 is a SEM image of a nickel thin film deposited in Example 1.

FIG. 4 is a SEM image of the nickel thin film after heat treatment in Example 1.

FIG. 5 is a SEM image of a graphene sheet formed in Example 1.

FIG. 6 is an optical microscope image of the graphene sheet formed in Example 1.

FIG. 7 is a SEM image of a graphene sheet according to Example 2.

FIG. 8 is an optical microscope image of the graphene sheet according to Example 2.

FIG. 9 shows a measurement result of sheet resistance of a graphene sheet according to Example 3.

FIG. 10 is a graph showing a change in average grain size of the nickel thin film depending on heat treatment time in a vacuum and in a hydrogen atmosphere.

FIG. 11 is a cross-sectional SEM image of a structure wherein a PMMA film is formed on a silicon substrate in Example 4.

FIG. 12 is a SEM image of a graphene sheet according to Example 4.

FIG. 13 shows a measurement result of thicknesses of graphenes according to Examples 4 to 7.

FIG. 14 shows a measurement result of transmittance of a graphene sheet according to Example b.

FIG. 15 shows an XRD measurement result of a copper foil before and after heat treatment in Example c.

FIG. 16 is a SEM image of a surface of the copper foil after heat treatment in Example c.

FIG. 17 shows an optical microscope image and a Raman measurement result of a graphene sheet formed on a bottom of the copper foil in Example c.

FIG. 18 shows an optical microscope image and a Raman measurement result of the graphene sheet transferred on a SiO₂/Si substrate in Example c.

### DETAILED DESCRIPTION OF THE EMBODIMENTS

Exemplary embodiments of the present disclosure will hereinafter be described in detail. However, the exemplary embodiment is illustrative only and is not to be construed to limit the present invention, and the present invention is just defined by the scope of the claims as described below.

A term “graphene” used in the present specification indicates that graphene having a polycyclic aromatic molecule formed by a plurality of carbon atoms connected by a covalent bond forms a layer. The carbon atoms connected by the covalent bond form a six-membered ring as a basic repeating unit, but may further include a five-membered ring and/or a seven-membered ring. Accordingly, the graphene appears to be a single layer of carbon atoms having a covalent bond (in general, an sp² bond).

The graphene may have various structures. These structures may vary depending on the amount of 5-membered rings and/or 7-membered rings included in the graphene.

The graphene may be the aforementioned single graphene layer, but a multilayer formed by laminating several single layers together may also be formed (In general, ten layers or less). The graphene has a thickness of 100 nm at most. In general, the graphene is saturated with hydrogen atoms at a side end thereof.

The graphene sheet has a representative characteristic that electrons flow as if the electrons have zero mass, which means that electrons flow at the speed of light in a vacuum. The graphene conventionally has a high electron mobility value ranging from about 10,000 to 100,000 cm²/Vs.

Contact between a plurality of layers of the graphene is surface contact and thus very low contact resistance is exhibited compared with carbon nanotubes having point contact.

Further, the graphene may be constituted to be very thin and thus a problem caused by surface roughness may be prevented.

Particularly, since the graphene having a predetermined thickness may have various electrical characteristics depending on crystal direction, electrical characteristics may be realized in a direction selected by a user. Accordingly, there is a merit in that a device may be easily designed.

Hereinafter, referring to the drawings, a graphene sheet as an exemplary embodiment of the present invention will be described.

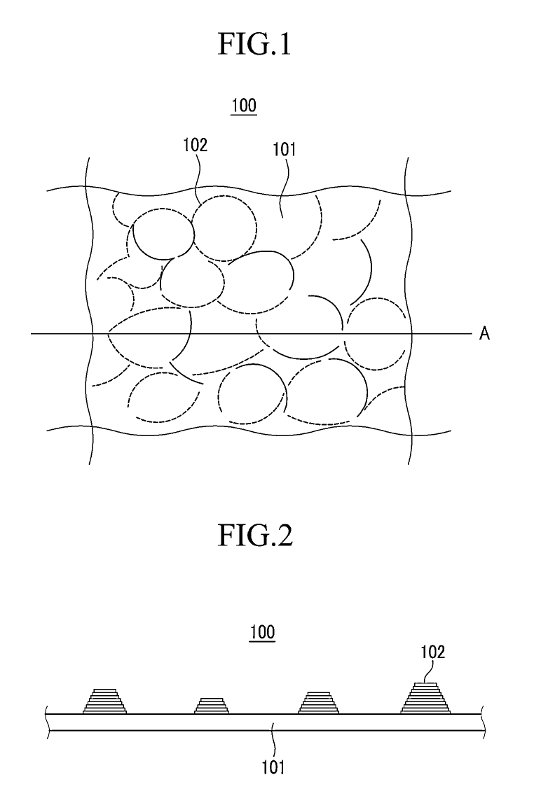

FIG. 1 is a top plan view of a graphene sheet 100 according to one embodiment of the present invention, and FIG. 2 is a cross-sectional view of the graphene sheet 100 according to one embodiment of the present invention. FIG. 2 is a cross-sectional view shown based on A shown in FIG. 1.

A graphene sheet 100 according to one embodiment of the present invention includes a lower sheet 101 including 1 to 20 layers of graphene, and a ridge 102 formed on the lower sheet 101 and including the graphene having more layers compared with the lower sheet 101. The ridge 102 has a form of a grain boundary of a metal.

The ridge 102 may include the graphene of 3 to 50 layers.

The ridge 102 may have a metal grain shape as shown in FIG. 1 as the top plan view. In FIG. 1, a portion represented by a dotted line or a solid line denotes the ridge 102, and the remaining portion denotes the lower sheet 101.

The shape of the metal grain may be amorphous, or may vary depending on a type, a thickness, a state (e.g., heat treatment in various conditions), or the like of the metal.

Further, the ridge 102 may be continuous or discontinuous. The solid line of FIG. 1 denotes a continuously formed ridge 102, and the dotted line denotes a discontinuously formed ridge 102.

The lower sheet 101 may include 1 to 20 layers of the graphene.

Further, the ridge 102 may include 3 to 50 layers of the graphene.

To be more specific, the lower sheet 101 may include 1 to 10 layers of the graphene, and the ridge 102 may include 3 to 30 layers of the graphene. To be more specific, the lower sheet 101 may include 1 to 5 layers of the graphene, and the ridge 102 may include 3 to 20 layers of the graphene.

A structure caused by a difference between layers of the lower sheet 101 and the ridge 102 will be specifically described with reference to FIG. 2 as the cross-sectional view of a portion A shown in FIG. 1.

In FIG. 2, the ridges 102 formed along the portion A of FIG. 1 may be formed at intervals corresponding to the size and the shape of the metal grain.

The reason why the ridge 102 is formed to have the aforementioned structure is that when the graphene sheet according to one embodiment of the present invention is manufactured, the graphene sheet is manufactured by using a diffusion method through a polycrystalline metal thin film and/or a metal foil.

The polycrystalline metal thin film and/or the metal foil have an intrinsic grain. The diffusion speed of carbon atoms according to the boundary of the grain is higher than the diffusion speed of the carbon atoms through a lattice structure in the grain at low temperatures, and thus the structure of the ridge 102 is formed. A more detailed method of manufacturing the graphene sheet according to one embodiment of the present invention will be described later.

The size of the metal grain may be 10 nm to 10 mm, and specifically 50 nm to 1 mm or 50 nm to 200 μm.

The size of the metal grain may vary depending on the method of manufacturing the graphene sheet according to one embodiment of the present invention as will be more specifically described later.

For example, when the graphene sheet according to one embodiment of the present invention is manufactured by using the metal thin film, the size of the metal grain may be 10 nm to 500 μm, 10 nm to 200 μm, 10 nm to 100 μm, or 10 nm to 50 μm.

As another example, when the graphene sheet according to one embodiment of the present invention is manufactured by using the metal foil, the size of the metal grain may be 50 nm to 10 mm, 50 nm to 1 mm, or 50 nm to 10 μm. When the metal foil is used as described above, an ex-situ heat treatment process of the metal foil may be performed to further increase the size of the metal grain.

The grain size may vary depending on a heat treatment temperature and a heat treatment atmosphere of the metal thin film and/or the metal foil used during a process of manufacturing the graphene sheet according to one embodiment of the present invention.

The metal may include Ni, Co, Fe, Pt, Au, Al, Cr, Cu, Mg, Mn, Mo, Rh, Si, Ta, Ti, W, U, V, Zr, Zn, Sr, Y, Nb, Tc, Ru, Pd, Ag, Cd, In, Re, Os, Ir, Pb, or a combination thereof, but is not limited thereto.

Further, the heat treatment temperature may vary depending on a subject substrate on which the graphene sheet is to be deposited. The heat treatment atmosphere may include a vacuum, an inert gas such as Ar and N₂, an inflow of a vapor such as H₂, O₂, and the like, or a mixture thereof. The inflow of H₂ may be useful to increase the grain size.

As a specific example, when the subject substrate on which the graphene sheet is to be deposited is an inorganic material substrate, since the inorganic material substrate generally has as excellent thermal characteristic and high abrasion resistance, the metal thin film and/or the metal foil may be heat-treated in a H₂ atmosphere at about 1000° C. to increase the grain size. In this case, the formed graphene sheet may have the ridges 102 at intervals of several micrometers to several millimeters. Specifically, the interval may be 1 μm to 500 μm, 5 μm to 200 μm, or 10 μm to 100 μm.

However, as described above, when the inorganic material substrate is used and the heat treatment temperature is reduced, since the grain size of the metal thin film and/or the metal foil is relatively reduced, the interval between the ridges 102 may be reduced to several tens of nanometers to several tens of micrometers.

As another example, when the subject substrate on which the graphene sheet is to be deposited is an organic material substrate, since an organic material is generally weak to heat, the metal thin film and/or the metal foil is heat-treated at about 200° C. or less. In this case, the size of the metal grain is relatively small, and the interval between the ridges 102 may be several tens of nanometers to several hundreds of nanometers. Specifically, the interval may be 10 nm to 900 nm, 30 nm to 500 nm, or 50 nm to 500 nm.

However, when the metal foil is heat-treated in advance and the metal foil is supplied onto the subject substrate, since the heat treatment temperature and the heat treatment atmosphere may be selected regardless of a kind of the subject substrate, the interval between the ridges 102 may be several hundreds of micrometers to several tens of millimeters. Specifically, the interval may be 100 μm to 10 mm, 100 μm to 1 mm, or 100 μm to 500 μm.

The subject substrate may include a group IV semiconductor substrate such as Si, Ge, SiGe, and the like; a group III-V compound semiconductor substrate such as GaN, AlN, GaAs, AlAs, GaP, and the like; a group II-VI compound semiconductor substrate such as ZnS, ZnSe, and the like; an oxide semiconductor substrate such as ZnO, MgO, sapphire, and the like; other insulator substrates such as glass, quartz, and SiO₂; or an organic material substrate such as a polymer, a liquid crystal, and the like.

In general, the subject substrate is not limited as long as it is one used for a display, an optoelectronic/electronic device, a battery, or a solar cell, and for a transistor, a sensor, or an organic/inorganic semiconductor device.

The lower sheet 101 may be a flat sheet. That is, the lower sheet 101 may not have creases and the like.

The reason why the lower sheet 101 of the graphene sheet according to one embodiment of the present invention may be a flat sheet is that the graphene is not manufactured by a conventional chemical vapor deposition (CVD) method.

When the graphene is manufactured by the conventional chemical vapor deposition method, the graphene is subjected to a step of supplying a carbon source on a metal through the chemical vapor deposition method at about 1000° C. and a step of rapidly reducing the temperature to room temperature.

The creases are formed in the graphene while the graphene is subjected to the step of rapidly reducing the temperature to room temperature as a subsequent step of the step of supplying the carbon source on metal at high temperatures among the aforementioned steps. It is caused by a difference in thermal expansion coefficients of the metal and the graphene.

Since the graphene according to the present invention may be manufactured without a rapid change in temperature, unlike the chemical vapor deposition method, the lower sheet 101 of the graphene sheet may be flat.

Light transmittance of the graphene sheet may be 60% or more, specifically 80% or more, more specifically 85% or more, and even more specifically 90% or more. When the graphene sheet satisfies the light transmittance in the aforementioned range, the graphene sheet may be appropriately used as an electron material of a transparent electrode or the like.

Sheet resistance of the graphene sheet may be 2000 Ω/square or less, specifically 1000 Ω/square or less, more specifically 274 Ω/square or less, and even more specifically 100 Ω/square or less. Since the graphene sheet according to one embodiment of the present invention does not include the creases in the lower sheet 101 and the lower sheet 101 of the graphene sheet is flat, the graphene sheet may have a low sheet resistance value. When the graphene sheet has the sheet resistance in the aforementioned range, the graphene sheet may be appropriately used as the electron material of the electrode or the like.

According to one embodiment of the present invention, a method of manufacturing a graphene sheet may include: (a) preparing a subject substrate, (b) supplying a metal foil on the subject substrate; (c) supplying a carbon source material on the metal foil; (d) heating the supplied carbon source material, subject substrate, and metal foil; (e) diffusing carbon atoms generated from the heated carbon source material due to thermal decomposition into the metal foil; and (f) forming the graphene sheet on the subject substrate by the carbon atoms diffused into the metal foil.

The subject substrate may be a group IV semiconductor substrate such as Si, Ge, SiGe, and the like; a group III-V compound semiconductor substrate such as GaN, AlN, GaAs, AlAs, GaP, and the like; a group II-VI compound semiconductor substrate such as ZnS, ZnSe, and the like; an oxide semiconductor substrate such as ZnO, MgO, sapphire, and the like; other insulator substrates such as glass, quartz, and SiO₂; or an organic material substrate such as a polymer, a liquid crystal, and the like. In general, the subject substrate is not limited as long as it is one used for the display, the optoelectronic/electronic device, the battery, or the solar cell, and for the transistor, the sensor, or the organic/inorganic semiconductor device.

The metal foil is supplied onto the subject substrate. This allows the carbon source material to be capable of being decomposed at a relatively low temperature due to a catalyst effect of the metal foil when the carbon source material is supplied in the subsequent step, and provides a path through which the decomposed carbon source material is capable of being diffused as individual atoms into the subject substrate.

The metal foil is a metal manufactured like thin paper, and generally has excellent flexibility.

The metal foil may be a metal including Ni, Co, Fe, Pt, Au, Al, Cr, Cu, Mg, Mn, Mo, Rh, Si, Ta, Ti, W, U, V, Zr, Zn, Sr, Y, Nb, Tc, Ru, Pd, Ag, Cd, In, Re, Os, Ir, Pb, or a combination thereof.

The metal foil means a commercially available metal foil, or a metal foil formed by a typical method such as plating and deposition. In general, the metal foil has various thicknesses ranging from several micrometers to several millimeters, and the grain size of the metal foil may be several tens of nanometers to several tens of micrometers.

If needed, a metal foil having the thickness of several micrometers or less may be manufactured and used. When the aforementioned range is satisfied, the graphene may be formed by the subsequent diffusion of the carbon atoms.

The carbon source material supplied in the step (c) may be a vapor, a liquid, a solid, or a combination thereof. More specific examples of the vapor carbon source material may include methane, ethane, propane, butane, isobutane, pentane, isopentane, neopentane, hexane, heptane, octane, nonane, decane, methene, ethene, propene, butene, pentene, hexene, heptene, octene, nonene, decene, ethyne, propyne, butyne, pentyne, hexyne, heptyne, octyne, nonyne, decyne, cyclomethane, cycloethine, cyclobutane, methylcyclopropane, cyclopentane, methylcyclobutane, ethylcyclopropane, cyclohexane, methylcyclopentane, ethylcyclobutane, propylcyclopropane, cycloheptane, methylcyclohexane, cyclooctane, cyclononane, cyclodecane, methylene, ethediene, allene, butadiene, pentadiene, isopyrene, hexadiene, heptadiene, octadiene, nonadiene, decadiene, and the like. More specific examples of the solid carbon source material may include highly-oriented pyrolytic graphite, graphite, amorphous carbon, diamond, spin-coated polymer-type source materials, and the like. More specific examples of the liquid carbon source material may include a gel-type source material manufactured by breaking a solid carbon source such as graphite, a highly-oriented pyrolytic graphite (HOPG) substrate, amorphous carbon, and the like, into pieces and dissolving the pieces in various alcohol solvents such as acetone, methanol, ethanol, pentanol, ethylene glycol, glycerin, and the like. The size of the solid carbon source may be 1 nm to 100 cm, 1 nm to 1 mm, or more specifically 1 nm to 100 μm.

A heating temperature of the step (d) may be room temperature to 1500° C., 30° C. to 1000° C., or 30° C. to 800° C., or more specifically 50° C. to 600° C. This is a temperature that is remarkably lower than a manufacturing temperature of a graphene thin film according to a general chemical vapor deposition method. A heating process in the aforementioned temperature range is advantageous in views of costs as compared with a conventional process, and may prevent transformation of the subject substrate originating from the high temperature. The maximum heating temperature may be reduced according to the subject substrate.

In the present specification, room temperature generally means a temperature of an environment in which the manufacturing method is performed. Accordingly, the range of the room temperature may vary depending on a season, a location, an interior condition, and the like.

Further, a heating time may be 1 second to 10 hours, 1 second to 1 hour, or more specifically 2 seconds to 20 minutes. The heating may be maintained for 1 second to 100 hours, 1 second to 10 hours, or more specifically 5 second to 3 hours.

A heating speed may be 0.1° C./sec to 500° C./sec, 0.3° C./sec to 300° C./sec, or more specifically 0.5° C./sec to 100° C./sec.

The heating temperature may be more appropriate when the carbon source material is a liquid or a solid.

For example, when the carbon source material is a vapor, the following heating condition is feasible.

The heating temperature may be room temperature to 1500° C., 300° C. to 1200° C., or more specifically 500° C. to 1000° C.

Further, the heating time may be 1 second to 10 hours, 1 second to 1 hour, or more specifically 2 seconds to 30 minutes. The heating may be maintained for 1 second to 100 hours, 1 second to 10 hours, or more specifically 1 minute to 5 hours.

The heating speed may be 0.1° C./sec to 500° C./sec, 0.3° C./sec to 300° C./sec, or more specifically 0.5° C./sec to 100° C./sec.

The heating temperature and time may be controlled to stably manufacture the desired graphene. In addition, the temperature and time may be regulated to control the thickness of the graphene.

The thermally decomposed carbon atoms present on the metal foil may be diffused into the metal foil. A diffusion principle is a spontaneous diffusion due to a carbon concentration gradient.

For a metal-carbon system, carbon solubility is generally several percent in metal, and the individual carbon atoms thermally decomposed at low temperatures due to the catalyst effect of the metal foil are dissolved into the metal foil. The dissolved carbon atoms are diffused on one surface of the metal foil due to the concentration gradient and then diffused into the metal foil. When the solubility of the carbon atoms on a lower portion of the surface of the subject substrate in the metal foil reaches a predetermined value, the graphene as a stable phase is precipitated on the other surface of the metal foil. Accordingly, the graphene sheet is formed between the subject substrate and the metal foil.

On the other hand, when the metal foil is adjacent to the carbon source material, the carbon source material is smoothly decomposed due to a catalyst operation of the metal foil. As a result, the decomposed carbon atoms may be spontaneously diffused due to the concentration gradient through dislocation, the grain boundary, or the like, which is a defect source present in a large amount in the polycrystalline metal foil.

The carbon atoms spontaneously diffused to reach the subject substrate may be diffused along an interface between the subject substrate and the metal foil to form the graphene sheet.

A diffusion mechanism of the carbon atoms in the metal foil may vary depending on a kind of the aforementioned carbon source material and heating conditions.

The heating temperature, the heating time, and the heating speed may be regulated to control the number of layers of the formed graphene sheet. The multilayered graphene sheet may be manufactured as aforementioned.

The graphene sheet may have a thickness ranging from 0.1 nm to about 100 nm, which is the thickness of the graphene of a single layer, preferably 0.1 to 10 nm, and more preferably 0.1 to 5 nm. When the thickness is more than 100 nm, the sheet is not defined as a graphene sheet but as graphite, which is beyond the range of the present invention.

After the graphene sheet is formed on the subject substrate, the metal foil is removed. Any remaining metal foil may be completely removed by an organic solvent and the like. In this process, a remaining carbon source material may be removed. The usable organic solvent includes hydrochloric acid, nitric acid, sulfuric acid, iron chloride, pentane, cyclopentane, hexane, cyclohexane, benzene, toluene, 1,4-dioxane, methylene chloride (CHCl₃), diethyl ether, dichloromethane, tetrahydrofuran, ethyl acetate, acetone, dimethyl formamide, acetonitrile, dimethyl sulfoxide, formic acid, n-butanol, isopropanol, m-propanol, ethanol, methanol, acetic acid, distilled water, and the like.

When the metal foil is patterned before supplying the carbon source material, the graphene sheet may be manufactured to have a desired geometry. A patterning method may include any common method used in a related art and thus will not be separately illustrated.

Further, before supplying the carbon source material, a method of spontaneously patterning the metal foil due to heat treatment may be used. In general, when a thinly-deposited metal foil is heat-treated at high temperatures, transformation may be performed from a two-dimensional thin film to a three-dimensional structure due to active movement of metal atoms, which may be used to selectively deposit the graphene sheet on the subject substrate.

The subject substrate may be a flexible substrate.

Since the metal foil may have flexibility, the bent graphene may be formed on the flexible subject substrate.

The substrate having the flexibility includes plastics such as polystyrene, polyvinyl chloride, nylon, polypropylene, acryl, phenol, melamine, epoxy, polycarbonate, polymethyl methacrylate, polymethyl(meth)acrylate, polyethyl methacrylate, and polyethyl(meth)acrylate, liquid crystal, glass, quartz, rubber, paper, or the like, but is not limited thereto.

According to another embodiment of the present invention, a method of manufacturing a graphene sheet is provided, which includes: (a) preparing a subject substrate; (b) supplying a metal foil on the subject substrate and heat-treating the metal foil and the subject substrate to increase a grain size of the metal foil; (c) supplying a carbon source material on the metal foil; (d) heating the supplied carbon source material, subject substrate, and metal foil; (e) diffusing carbon atoms generated from the heated carbon source material due to thermal decomposition into the metal foil; and (f) forming the graphene sheet on the subject substrate by the carbon atoms diffused into the metal foil.

As compared with one embodiment of the present invention, another embodiment of the present invention further includes heat-treating the metal foil to increase the grain size of the metal foil after the metal foil is supplied in the step (b).

Since the grain size of the supplied metal foil is relatively small, when heat treatment is performed in a special atmosphere such as ultra-high vacuum, a hydrogen atmosphere, or the like in order to increase the grain size, orientation of the grain may be controlled and the grain size may be increased.

In this case, the heat treatment condition may vary depending on a kind of the subject substrate.

First, when the subject substrate is an inorganic material such as a semiconductor substrate such as Si, GaAs, and the like, or an insulator substrate such as SiO₂, a heating temperature may be 400° C. to 1400° C., 400° C. to 1200° C., or more specifically 600° C. to 1200° C.

A heating time may be 1 second to 10 hours, 1 second to 1 hour, or more specifically 3 seconds to 30 minutes.

The heating may be maintained for 10 seconds to 10 hours, 30 seconds to 3 hours, or more specifically 1 minute to 1 hour.

A heating speed may be 0.1° C./sec to 100° C./sec, 0.3° C./sec to 30° C./sec, or more specifically 0.5° C./sec to 10° C./sec.

The heating may be performed in a vacuum, or by inflowing an inert gas such as Ar and N₂, a vapor such as H₂, O₂, and the like, and a mixture thereof. The inflow of H₂ may be useful to increase the grain size.

When the subject substrate is an organic material such as a polymer, a liquid crystal, and the like, the heating temperature may be 30° C. to 500° C., 30° C. to 400° C., or more specifically 50° C. to 300° C.

The heating time may be 1 second to 10 hours, 1 second to 30 minutes, or more specifically 3 seconds to 10 minutes.

The heating may be maintained for 10 seconds to 10 hours, 30 seconds to 5 hours, or more specifically 1 minute to 1 hour.

The heating speed may be 0.1° C./sec to 100° C./sec, 0.3° C./sec to 30° C./sec, or more specifically 0.5° C./sec to 10° C./sec.

As described above, the heating may be performed in a vacuum, or by inflowing an inert gas such as Ar and N₂, a vapor such as H₂, O₂, and the like, and a mixture thereof. The inflow of H₂ may be useful to increase the grain size.

When the metal foil is heat-treated through the aforementioned method, the grain size in the metal foil is generally increased by about 2 times to 1000 times.

Descriptions regarding other constitutions are the same and thus will be omitted.

For the aforementioned method of manufacturing the graphene sheet according to the embodiment of the present invention, a liquid and/or solid carbon source may be used to manufacture a large-scale graphene sheet having a level of several millimeters to several centimeters or more at low temperatures.

Further, the graphene sheet may be directly formed on a semiconductor, an insulator, and an organic material substrate, and thus a transfer process may be omitted.

As a specific example, when the graphene sheet manufactured according to the method of manufacturing the graphene sheet according to the embodiment of the present invention is used as an active layer of a conventional Si-based TFT, equipment used in a Si process that is sensitive to a conventional process temperature may be used.

In the course of industrializing the graphene sheet, growth may be directly performed on the substrate without low temperature growth and a transfer process. Accordingly, when mass production is realized, enormous economic gains and improvement in yield are expected. Particularly, crumpling, tearing, or the like of the graphene easily occurs in transfer as the size of the graphene is increased. Accordingly, it is greatly required for the transfer process to be omitted in order to realize the mass production.

Further, the carbon source material used in the method of manufacturing the graphene according to the embodiment of the present invention is very low-priced as compared with using a conventional highly pure carbonized gas.

According to yet another embodiment of the present invention, a method of manufacturing a graphene sheet is provided, which includes: (a) preparing a subject substrate; (b) supplying a metal foil on the subject substrate; (c) heating the subject substrate and the metal foil; (d) supplying a carbon source material on the metal foil; (e) diffusing carbon atoms generated from the carbon source material due to thermal decomposition into the metal foil; and (f) forming the graphene sheet on the subject substrate by the carbon atoms diffused into the metal foil.

The aforementioned manufacturing method is different from the method of manufacturing the graphene sheet according to one embodiment of the present invention in views of the order of the step (c) of heating the subject substrate and the metal foil and the step (d) of supplying the carbon source material on the metal foil.

A heating temperature of the step (c) may be room temperature to 1500° C., 300° C. to 1200° C., or more specifically 300° C. to 1000° C. This is a temperature that is remarkably lower than a manufacturing temperature of a graphene thin film according to a general chemical vapor deposition method. A heating process in the aforementioned temperature range is advantageous in views of costs as compared to a conventional process, and may prevent transformation of the subject substrate originating from the high temperature.

Further, a heating time may be 1 second to 10 hours, 1 second to 1 hour, or more specifically 2 seconds to 30 minutes. The heating may be maintained for 1 second to 100 hours, 1 second to 10 hours, or more specifically 1 minute to 3 hours.

A heating speed may be 0.1° C./sec to 500° C./sec, or more specifically 0.5° C./sec to 100° C./sec.

The heating temperature and time may be controlled to stably manufacture the desired graphene sheet. Further, the temperature and time may be adjusted to control the thickness of the graphene sheet.

A matter regarding the heating condition may be more suitable for the case where the carbon source material is a vapor.

Descriptions regarding other constitutions are the same as those of the method of manufacturing the graphene according to one embodiment of the present invention.

According to still another embodiment of the present invention, a method of manufacturing a graphene sheet is provided, which includes: (a) preparing a subject substrate; (b) supplying a metal foil on the subject substrate and heat-treating the metal foil and the subject substrate to increase a grain size of the metal foil; (c) heating the subject substrate and the metal foil; (d) supplying a carbon source material on the heated metal foil; (e) diffusing carbon atoms generated from the supplied carbon source material due to thermal decomposition into the metal foil; and (f) forming the graphene sheet on the subject substrate by the carbon atoms diffused into the metal foil.

Still another embodiment of the present invention further includes heat-treating the metal foil to increase the grain size of the metal foil after the metal foil is supplied in the step (b).

Since the grain size of the supplied metal foil is relatively small, when heat treatment is performed in a special atmosphere such as ultra-high vacuum, a hydrogen atmosphere, or the like in order to increase the grain size, orientation of the grain may be controlled and the grain size may be increased.

In this case, the heat treatment condition may vary depending on a kind of the subject substrate.

First, when the subject substrate is an inorganic material such as a semiconductor substrate such as Si, GaAs, and the like, or an insulator substrate such as SiO₂, a heating temperature may be 400° C. to 1400° C., 400° C. to 1200° C., or more specifically 600° C. to 1200° C.

A heating time may be 1 second to 10 hours, 1 second to 1 hour, or more specifically 3 seconds to 30 minutes.

The heating may be maintained for 10 seconds to 10 hours, 30 seconds to 3 hours, or more specifically 1 minute to 1 hour.

The heating speed may be 0.1° C./sec to 100° C./sec, 0.3° C./sec to 30° C./sec, or more specifically 0.5° C./sec to 10° C./sec.

The heating may be performed in a vacuum, or by inflowing an inert gas such as Ar and N₂, a vapor such as H₂, O₂, and the like, and a mixture thereof. The inflow of H₂ may be useful to increase the grain size.

When the subject substrate is an organic material such as a polymer, a liquid crystal, and the like, the heating temperature may be 30° C. to 500° C., 30° C. to 400° C., or more specifically 50° C. to 300° C.

The heating time may be 1 second to 10 hours, 1 second to 30 minutes, or more specifically 3 seconds to 10 minutes.

The heating may be maintained for 10 seconds to 10 hours, 30 seconds to 5 hours, or more specifically 1 minute to 1 hour.

The heating speed may be 0.1° C./sec to 100° C./sec, 0.3° C./sec to 30° C./sec, or more specifically 0.5° C./sec to 10° C./sec.

As described above, the heating may be performed in a vacuum, or by inflowing an inert gas such as Ar and N₂, a vapor such as H₂, O₂, and the like, and a mixture thereof. The inflow of H₂ may be useful to increase the grain size.

When the metal foil is heat-treated through the aforementioned method, the grain size in the metal foil is generally increased by about 2 times to 1000 times.

Descriptions regarding other constitutions are the same as those of the previous embodiment of the present invention and thus will be omitted.

According to still another embodiment of the present invention, a method of manufacturing a graphene sheet is provided, which includes: (a) preparing a subject substrate and a metal foil; (b) heat-treating the metal foil to increase a grain size of the metal foil; (c) supplying the metal foil having the increased grain size on the subject substrate; (d) supplying a carbon source material on the metal foil; (e) heating the supplied carbon source material, subject substrate, and metal foil; (f) diffusing carbon atoms generated from the heated carbon source material due to thermal decomposition into the metal foil; and (g) forming the graphene sheet on the subject substrate by the carbon atoms diffused into the metal foil.

Since the grain size of the metal foil is relatively small, when heat treatment is performed in a special atmosphere such as ultra-high vacuum, a hydrogen atmosphere, or the like in order to increase the grain size, orientation of the grain may be controlled and the grain size may be increased.

The heat treatment step for increasing the grain size of the metal foil may be performed separately with respect to the subject substrate. As described above, when the metal foil is heat-treated separately with respect to the subject substrate, damage to the subject substrate due to the heat treatment step may be minimized.

In this case, a heat treatment condition may be as follows.

A heating temperature may be 50° C. to 3000° C., 500° C. to 2000° C., or more specifically 500° C. to 1500° C. The heating temperature may vary depending on a kind of the metal foil. A temperature that is lower than a melting point of the metal foil may be considered as the maximum temperature.

A heating time may be 1 second to 10 hours, 1 second to 1 hour, or more specifically 1 second to 30 minutes.

The heating may be maintained for 10 seconds to 10 hours, 30 seconds to 5 hours, or more specifically 1 minute to 3 hour.

A heating speed may be 0.1° C./sec to 500° C./sec, 0.3° C./sec to 50° C./sec, or more specifically 0.5° C./sec to 10° C./sec.

The heating may be performed in a vacuum, or by inflowing an inert gas such as Ar and N₂, a vapor such as H₂, O₂, and the like, and a mixture thereof. The inflow of H₂ may be useful to increase the grain size.

When the metal foil is heat-treated through the aforementioned method, the grain size in the metal foil may be generally increased by several hundreds of micrometers to several tens of millimeters.

The metal foil having the increased grain size may be supplied onto the subject substrate.

This allows the carbon source material to be capable of being decomposed at a relatively low temperature due to a catalyst effect of the metal foil when the carbon source material is supplied in the subsequent step, and provides a path through which the decomposed carbon source material is capable of being diffused as individual atoms into the subject substrate.

Subsequently, the carbon source material may be supplied onto the metal foil.

The heating temperature of the step (e) may be room temperature to 1500° C., 30° C. to 1000° C., or more specifically 50° C. to 800° C. This is a temperature that is remarkably lower than a manufacturing temperature of a graphene thin film according to a general chemical vapor deposition method. A heating process in the aforementioned temperature range is advantageous in views of costs as compared with a conventional process, and may prevent transformation of the subject substrate originating from the high temperature. For the heating temperature, the maximum heating temperature may be reduced according to the subject substrate.

Further, the heating time may be 1 second to 10 hours, 1 second to 1 hour, or more specifically 2 seconds to 30 minutes. The heating may be maintained for 1 second to 100 hours, 1 second to 10 hours, or more specifically 5 seconds to 3 hours.

The heating speed may be 0.1° C./sec to 500° C./sec, 0.3° C./sec to 300° C./sec, or more specifically 0.5° C./sec to 100° C./sec.

The heating temperature may be more appropriate when the carbon source material is a liquid or a solid.

For example, when the carbon source material is a vapor, the following heating condition is feasible.

The heating temperature may be room temperature to 1500° C., 300° C. to 1200° C., or more specifically 500° C. to 1000° C.

Further, the heating time may be 1 second to 10 hours, 1 second to 1 hour, or more specifically 2 seconds to 30 minutes. The heating may be maintained for 1 second to 100 hours, 1 second to 10 hours, or more specifically 1 minute to 5 hours.

The heating speed may be 0.1° C./sec to 500° C./sec, 0.3° C./sec to 300° C./sec, or more specifically 0.5° C./sec to 100° C./sec.

The heating temperature and time may be controlled to stably manufacture the desired graphene sheet. Further, the temperature and time may be adjusted to control the thickness of the graphene sheet.

The thermally decomposed carbon atom present on the metal foil may be diffused into the metal foil. A diffusion principle is spontaneous diffusion due to a carbon concentration gradient.

According to still another embodiment of the present invention, a method of manufacturing a graphene sheet is provided, which includes: (a) preparing a subject substrate and a metal foil; (b) heat-treating the metal foil to increase a grain size of the metal foil; (c) supplying the metal foil having the increased grain size on the subject substrate; (d) heating the subject substrate and the metal foil; (e) supplying a carbon source material on the metal foil; (f) diffusing carbon atoms generated from the carbon source material due to thermal decomposition into the metal foil; and (g) forming the graphene sheet on the subject substrate by the carbon atoms diffused into the metal foil.

The aforementioned manufacturing method is different from the method of manufacturing the graphene sheet according to one embodiment of the present invention in views of the order of the step (d) of heating the subject substrate and the metal foil and the step (e) of supplying the carbon source material on the metal foil.

A heating temperature of the step (d) may be room temperature to 1500° C., 300° C. to 1200° C., or more specifically 300° C. to 1000° C. This is a temperature that is remarkably lower than a temperature of the graphene sheet according to a general chemical vapor deposition method. A heating process in the aforementioned temperature range is advantageous in views of costs as compared with a conventional process, and may prevent transformation of the subject substrate originating from a high temperature.

Further, a heating time may be 1 second to 10 hours, 1 second to 1 hour, or more specifically 2 seconds to 30 minutes. The heating may be maintained for 1 second to 100 hours, 1 second to 10 hours, or more specifically 1 minute to 3 hours.

A heating speed may be 0.1° C./sec to 500° C./sec, or more specifically 0.5° C./sec to 100° C./sec.

The heating temperature and time may be controlled to stably manufacture the desired graphene sheet. Further, the temperature and time may be adjusted to control the thickness of the graphene sheet.

A matter regarding the heating condition may be more suitable for the case where the carbon source material is a vapor.

Descriptions regarding other constitutions are the same as those of the method of manufacturing the graphene sheet according to one embodiment of the present invention.

According to still another embodiment of the present invention, a method of manufacturing a graphene sheet may include: (a) preparing a subject substrate; (b) forming a metal thin film on the subject substrate and heat-treating the metal thin film to increase a grain size of the metal thin film; (c) supplying a carbon source material onto the metal thin film; (d) heating the supplied carbon source material, subject substrate, and metal thin film; (e) diffusing carbon atoms generated from the heated carbon source material due to thermal decomposition into the metal thin film; and (f) forming the graphene sheet on the subject substrate by the carbon atoms diffused into the metal thin film.

The subject substrate is the same as that of one embodiment of the present invention and thus will be omitted.

The metal thin film may be formed on the subject substrate. This allows the carbon source material to be capable of being decomposed at a relatively low temperature due to a catalyst effect of the metal thin film when the carbon source material is supplied in the subsequent step. Carbon of the decomposed carbon source material is present in an atom form on a surface of the metal thin film. For a vapor carbon source material, a remaining hydrogen group after decomposition is discharged in a hydrogen gas form.

The metal thin film may include at least one metal selected from the group consisting of Ni, Co, Fe, Pt, Au, Al, Cr, Cu, Mg, Mn, Mo, Rh, Si, Ta, Ti, W, U, V, Zr, Zn, Sr, Y, Nb, Tc, Ru, Pd, Ag, Cd, In, Re, Os, Ir, and Pb.

The metal thin film may be formed by using a vapor deposition method such as an evaporation method, sputtering, a chemical vapor deposition method, and the like.

When the metal thin film is deposited on the subject substrate, a deposition condition of the metal thin film may vary depending on a kind of the subject substrate.

First, when the metal thin film is deposited on an inorganic material substrate such as a semiconductor substrate such as Si, GaAs, and the like or an insulator substrate such as SiO₂, a heating temperature may be room temperature to 1200° C., or more specifically room temperature to 1000° C.

A heating time may be 1 second to 10 hours, 1 second to 30 minutes, or more specifically 3 seconds to 10 minutes.

The heating may be maintained for 10 seconds to 10 hours, 30 seconds to 3 hours, or more specifically 30 seconds to 90 minutes.

A heating speed may be 0.1° C./sec to 100° C./sec, 0.3° C./sec to 30° C./sec, or more specifically 0.5° C./sec to 10° C./sec.

Further, when the metal thin film is deposited on an organic material substrate such as a polymer, a liquid crystal, and the like, the heating temperature may be room temperature to 400° C., room temperature to 200° C., or more specifically room temperature to 150° C.

The heating time may be 1 second to 2 hours, 1 second to 20 minutes, or more specifically 3 seconds to 10 minutes.

The heating may be maintained for 10 seconds to 10 hours, 30 seconds to 3 hours, or more specifically 30 seconds to 90 minutes.

The heating speed may be 0.1° C./sec to 100° C./sec, 0.3° C./sec to 30° C./sec, or more specifically 0.5° C./sec to 10° C./sec.

The grain size of the metal thin film largely depends on a kind of a lower subject substrate and the deposition condition.

When the lower subject substrate has high crystallinity like a semiconductor substrate such as Si, GaAs, and the like, the grain size may be about several tens of nanometers (room temperature) to several micrometers (1000° C.) depending on a deposition temperature. When the lower subject substrate is amorphous like SiO₂, the grain size may be about several nanometers (room temperature) to several hundreds of nanometers (1000° C.). When the lower subject substrate is formed of an organic material such as a polymer and a liquid crystal, the grain size may be about several nanometers (room temperature) to several hundreds of nanometers (400° C.).

Since the grain size of the deposited metal thin film is relatively small, when heat treatment is performed in a special atmosphere such as ultra-high vacuum, a hydrogen atmosphere, or the like in order to increase the grain size, orientation of the grain may be controlled and the grain size may be increased.

In this case, a heat treatment condition may vary depending on a kind of the subject substrate.

First, when the subject substrate is an inorganic material such as a semiconductor substrate such as Si, GaAs, and the like, or an insulator substrate such as SiO₂, the heating temperature may be 400° C. to 1400° C., 400° C. to 1200° C., or more specifically 600° C. to 1200° C.

The heating time may be 1 second to 10 hours, 1 second to 30 minutes, or more specifically 3 seconds to 10 minutes.

The heating may be maintained for 10 seconds to 10 hours, 30 seconds to 1 hour, or more specifically 1 minute to 20 minutes.

The heating speed may be 0.1° C./sec to 100° C./sec, 0.3° C./sec to 30° C./sec, or more specifically 0.5° C./sec to 10° C./sec.

The heating may be performed in a vacuum, or by inflowing an inert gas such as Ar and N₂, a vapor such as H₂, O₂, and the like, and a mixture thereof. The inflow of H₂ may be useful to increase the grain size.

When the subject substrate is an organic material such as a polymer, a liquid crystal, and the like, the heating temperature may be 30° C. to 400° C., 30° C. to 300° C., or more specifically 50° C. to 200° C.

The heating time may be 1 second to 10 hours, 1 second to 30 minutes, or more specifically 3 seconds to 5 minutes.

The heating may be maintained for 10 seconds to 10 hours, 30 seconds to 1 hour, or more specifically 1 minute to 20 minutes.

The heating speed may be 0.1° C./sec to 100° C./sec, 0.3° C./sec to 30° C./sec, or more specifically 0.5° C./sec to 10° C./sec.

As described above, the heating may be performed in a vacuum, or by inflowing an inert gas such as Ar and N₂, a vapor such as H₂, O₂, and the like, and a mixture thereof. The inflow of H₂ is useful to increase the grain size.

When the metal thin film is heat-treated through the aforementioned method, the grain size in the metal thin film is generally increased by about 2 times to 1000 times.

A thickness of the metal thin film may be 1 nm to 10 μm, 10 nm to 1 μm, or more specifically 30 nm to 500 nm. Only when the thin film within the aforementioned range is formed can the graphene sheet be formed by subsequent diffusion of the carbon atoms.

The carbon source material supplied in the step (c) may be a vapor, a liquid, a solid, or a combination thereof. More specific examples of the vapor carbon source material may include methane, ethane, propane, butane, isobutane, pentane, isopentane, neopentane, hexane, heptane, octane, nonane, decane, methene, ethene, propene, butene, pentene, hexene, heptene, octene, nonene, decene, ethyne, propyne, butyne, pentyne, hexyne, heptyne, octyne, nonyne, decyne, cyclomethane, cycloethine, cyclobutane, methylcyclopropane, cyclopentane, methylcyclobutane, ethylcyclopropane, cyclohexane, methylcyclopentane, ethylcyclobutane, propylcyclopropane, cycloheptane, methylcyclohexane, cyclooctane, cyclononane, cyclodecane, methylene, ethediene, allene, butadiene, pentadiene, isopyrene, hexadiene, heptadiene, octadiene, nonadiene, decadiene, and the like. More specific examples of the solid carbon source material may include highly-oriented pyrolytic graphite, graphite, amorphous carbon, diamond, spin-coated polymer-type source materials, and the like. More specific examples of the liquid carbon source material may include a gel-type source material prepared by breaking a solid carbon source such as graphite, a highly-oriented pyrolytic graphite (HOPG) substrate, amorphous carbon, and the like, into pieces and dissolving the pieces in various alcohol solvents such as acetone, methanol, ethanol, pentanol, ethylene glycol, glycerin, and the like. The size of the solid carbon source may be 1 nm to 100 cm, 1 nm to 1 mm, or more specifically 1 nm to 100 μm.

The heating temperature of the step (d) may be room temperature to 1000° C., 30° C. to 600° C., or more specifically 35° C. to 300° C. This is a temperature that is remarkably lower than a manufacturing temperature of a graphene thin film according to a general chemical vapor deposition method. A heating process in the aforementioned temperature range is advantageous in views of costs as compared with a conventional process, and may prevent transformation of the subject substrate originating from a high temperature.

Further, the heating time may be 1 second to 10 hours, 1 second to 30 minutes, or more specifically 2 seconds to 10 minutes. The heating may be maintained for 10 seconds to 10 hours, 30 seconds to 1 hour, or more specifically 1 minute to 20 minutes.

The heating speed may be 0.1° C./sec to 100° C./sec, 0.3° C./sec to 30° C./sec, or more specifically 0.5° C./sec to 10° C./sec.

The heating temperature may be more appropriate when the carbon source material is the liquid or the solid.

For example, when the carbon source material is the vapor, the following heating condition is feasible.

The heating temperature may be 300° C. to 1400° C., 500° C. to 1200° C., or more specifically 500° C. to 1000° C.

Further, the heating time may be 1 second to 24 hours, 1 second to 3 hours, or more specifically 2 seconds to 1 hour. The heating may be maintained for 10 seconds to 24 hours, 30 seconds to 1 hour, or more specifically 1 minute to 30 minutes.

The heating speed may be 0.1° C./sec to 500° C./sec, 0.3° C./sec to 300° C./sec, or more specifically 0.3° C./sec to 100° C./sec.

The heating temperature and time may be controlled to stably manufacture the desired graphene sheet. Further, the temperature and time may be adjusted to control the thickness of the graphene sheet.

The thermally decomposed carbon atom present on the metal thin film may be diffused into the metal foil. A diffusion principle is a spontaneous diffusion due to a carbon concentration gradient.

For a metal-carbon system, the carbon atoms have solubility of about several percent in metal and thus are dissolved in one surface of the metal thin film. The dissolved carbon atoms are diffused on one surface of the metal thin film due to the concentration gradient and then diffused into the metal thin film. When the solubility of the carbon atoms in the metal thin film reaches a predetermined value, the graphene is precipitated on the other surface of the metal thin film. Accordingly, the graphene is formed between the subject substrate and the metal thin film.

Meanwhile, when the metal thin film is adjacent to the carbon source material, the carbon source material is smoothly decomposed due to a catalyst operation of the metal thin film. As a result, the carbon atoms decomposed when the metal-carbon system is formed may be spontaneously diffused due to the concentration gradient through dislocation, the grain boundary, or the like, which is a defect source present in a large amount in the polycrystalline metal thin film. The carbon atoms spontaneously diffused to reach the subject substrate may be diffused along an interface between the subject substrate and the metal thin film to form the graphene. A diffusion mechanism of the carbon atoms by dissolution may vary depending on a kind of the aforementioned carbon source material and heating conditions.

The heating temperature, the heating time, and the heating speed may be regulated to control the number of layers of the formed graphene sheet. The multilayer graphene sheet may be manufactured in the aforementioned way.

The graphene sheet may have a thickness ranging from 0.1 nm to about 100 nm, which is the thickness of the graphene of a single layer, preferably 0.1 to 10 nm, and more preferably 0.1 to 5 nm. When the thickness is more than 100 nm, the sheet is not defined as graphene as but graphite, which is beyond the range of the present invention.

Subsequently, the metal thin film may be removed by an organic solvent and the like. In this process, a remaining carbon source material may be removed. The usable organic solvent includes hydrochloric acid, nitric acid, sulfuric acid, iron chloride, pentane, cyclopentane, hexane, cyclohexane, benzene, toluene, 1,4-dioxane, methylene chloride (CHCl₃), diethyl ether, dichloromethane, tetrahydrofuran, ethyl acetate, acetone, dimethyl formamide, acetonitrile, dimethyl sulfoxide, formic acid, n-butanol, isopropanol, m-propanol, ethanol, methanol, acetic acid, distilled water, and the like.

When the metal thin film is patterned before supplying the carbon source material, the graphene sheet may be manufactured to have a desired geometry. A patterning method may include any common method used in a related art and thus will not be separately illustrated.

Further, before supplying the carbon source material, a method of spontaneously patterning the metal thin film due to heat treatment may be used. In general, when a thinly-deposited metal thin film is heat-treated at high temperatures, transformation may be performed from a two-dimensional thin film to a three-dimensional structure due to active movement of metal atoms, which may be used to selectively deposit the graphene sheet on the subject substrate.

According to still another embodiment of the present invention, a method of manufacturing a graphene sheet may include: (a) preparing a subject substrate; (b) forming a metal thin film on the subject substrate and heat-treating the metal thin film to increase a grain size of the metal thin film; (c) heating the subject substrate and the metal thin film; (d) supplying a carbon source material on the heated metal thin film; (e) diffusing carbon atoms generated from the supplied carbon source material due to thermal decomposition into the metal thin film; and (f) forming the graphene sheet on the subject substrate by the carbon atoms diffused into the metal thin film.

A heating temperature of the step (c) may be 400° C. to 1200° C., 500° C. to 1000° C., or more specifically 500° C. to 900° C. This is a temperature that is remarkably lower than a manufacturing temperature of a graphene thin film according to a general chemical vapor deposition method. A heating process in the aforementioned temperature range is advantageous in views of costs as compared with a conventional process, and may prevent transformation of the subject substrate originating from a high temperature.

Further, a heating time may be 10 seconds to 1 hour, or more specifically 1 minute to 20 minutes. The heating may be maintained for 10 seconds to 24 hours, 30 seconds to 2 hours, or more specifically 1 minute to 1 hour.

A heating speed may be 0.1° C./sec to 300° C./sec, or more specifically 0.3° C./sec to 100° C./sec.

The heating temperature and time may be controlled to stably manufacture the desired graphene sheet. Further, the temperature and time may be adjusted to control the thickness of the graphene sheet.

A matter regarding the heating condition may be more suitable for the case where the carbon source material is a vapor.

Descriptions regarding other constitutions are the same and thus will be omitted.

Further, the step (b) and the step (c) may be simultaneously performed.

For the aforementioned method of manufacturing the graphene sheet according to one embodiment of the present invention, a liquid and/or a solid carbon source may be used to manufacture a large-scale graphene sheet having a level of several millimeters to several centimeters or more at low temperatures.

Further, the graphene sheet may be directly formed on a semiconductor, an insulator, and an organic material substrate, and thus a transfer process may be omitted.

As a specific example, when the graphene sheet manufactured according to the method of manufacturing the graphene sheet according to one embodiment of the present invention is used as an active layer of a conventional Si-based TFT, equipment used in a Si process that is sensitive to a conventional process temperature may be used.

In the course of industrializing the graphene sheet, growth may be directly performed on the substrate without low temperature growth and a transfer process. Accordingly, when mass production is realized, enormous economic gains and improvement in yield are expected. Particularly, crumpling, tearing, or the like of the graphene sheet easily occurs in transfer as the size of the graphene sheet is increased. Accordingly, it is greatly required for the transfer process to be omitted in order to realize the mass production.

Further, the carbon source material used in the method of manufacturing the graphene sheet according to one embodiment of the present invention is very low-priced as compared with a conventional highly pure carbonized gas.

According to still another embodiment of the present invention, a transparent electrode including the graphene sheet manufactured according to the aforementioned method is provided.

The graphene sheet is used as a transparent electrode. Accordingly, the transparent electrode has excellent electrical characteristics, that is, high conductivity, low contact resistance, and the like. Since the graphene sheet is very thin and flexible, a bendable transparent electrode may be manufactured.

The transparent electrode has excellent conductivity according to a use of the graphene sheet, and thus target conductivity may be secured with a small thickness. Accordingly, the transparent electrode has a transparency improvement effect.

Transparency of the transparent electrode is preferably 60 to 99.9%, and sheet resistance is preferably 1 Ω/square to 2000 Ω/square.

Since the transparent electrode according to one embodiment of the present invention, to which the graphene sheet obtained by the manufacturing method according to one embodiment of the present invention is applied, may be manufactured by a simple process, the transparent electrode has characteristics of high economic efficiency, high conductivity, and excellent film uniformity. Particularly, the transparent electrode may be manufactured to have a large area at a low temperature, and the thickness of the graphene sheet may be freely controlled such that it is easy to control transmittance. Further, the transparent electrode is flexible and thus may be applied to any field requiring a transparent electrode that is easy to handle and is capable of being bent.

As the field to which the transparent electrode including the graphene sheet is applied, various display fields, for example, liquid crystal displays, electronic paper displays, organic/inorganic optoelectronic devices, and batteries, and cell fields, for example, solar cells and the like, may be availably used.

As described above, when the transparent electrode according to the present invention is used in the display, the display may be freely bent, and thus convenience is increased. For the solar cell, when the transparent electrode according to one embodiment of the present invention is used, the solar cell may have various bending structures according to a movement direction of light to efficiently use light, and thus photo-efficiency may be improved.

When the transparent electrode including the graphene sheet according to one embodiment of the present invention is used in various devices, it is preferable that the thickness be appropriately controlled in consideration of transparency. For example, since the transparent electrode may be formed at a thickness of 0.1 to 100 nm, when the thickness of the transparent electrode is more than 100 nm, transparency may deteriorate to reduce photo-efficiency. When the thickness is less than 0.1 nm, sheet resistance may be excessively reduced or the film of the graphene sheet may be non-uniform, which is not preferable.

Examples of the solar cell adapting the transparent electrode including the graphene sheet according to one embodiment of the present invention include a dye-sensitized solar cell. The dye-sensitized solar cell includes a semiconductor electrode, an electrolyte layer, and an opposed electrode. The semiconductor electrode is formed of a conductive transparent substrate and a photoabsorption layer. The dye-sensitized solar cell is completed by applying a colloid solution of nanoparticle oxides on a conductive glass substrate, heating the resulting glass substrate in an electric furnace at high temperatures, and adsorbing a dye.

The transparent electrode including the graphene sheet according to one embodiment of the present invention is used as the conductive transparent substrate. The transparent electrode may be obtained by directly forming the graphene sheet according to one embodiment of the present invention on the transparent substrate. As the transparent substrate, for example, a transparent polymer material such as polyethylene terephthalate, polycarbonate, polyimide, polyamide, polyethylene naphthalate, or a copolymer thereof, or a glass substrate may be used. The same is applied to an opposed electrode.

In order to manufacture the dye-sensitized solar cell having a bendable structure, for example, a cylindrical structure, it is preferable for the opposed electrode as well as the transparent electrode to be soft and flexible.

The nanoparticle oxides used in the solar cell are semiconductor particulates, and preferably an N-type semiconductor where conductive band electrons act as a carrier under photo-excitement to supply an anode current. Specific examples thereof may include TiO₂, SnO₂, ZnO₂, WO₃, Nb₂O₅, Al₂O₃, MgO, TiSrO₃, and the like, and particularly preferably anatase-type TiO₂. Moreover, the metal oxide is not limited thereto, and may be used alone or as a mixture of two or more. It is preferable that the semiconductor particulate have a large surface area so that the dye adsorbed on the surface may absorb more light, and thus have a particle diameter of about 20 nm or less.

Further, the dye may include any dye that is generally used in a solar cell or photoelectric cell field without limit, but is preferably a ruthenium complex. As the ruthenium complex, RuL₂(SCN)₂, RuL₂ (H₂O)₂, RuL₃, RuL₂, and the like may be used (L in the formula indicates 2,2′-bipyridyl-4,4′-dicarboxylate and the like). However, the dye has no particular limit as long as the dye has a charge-separating function to exhibit a sensitizing operation. Examples of the dye may include a xanthene-based colorant such as rhodamine B, rose bengal, eosine, erythrosine, and the like, a cyanine-based colorant such as quinocyanine, cryptocyanine, and the like, a basic dye such as phenosafranine, cabri blue, thiosine, methylene blue, and the like, a porphyrin-based compound such as chlorophyl, zinc porphyrin, magnesium porphyrin, and the like, a complex compound such as other azo colorants, a phthalocyanine compound, ruthenium trisbipyridyl, and the like, an anthraquinone-based colorant, a polycyclic quinone-based colorant, and the like other than a ruthenium complex, and may be used alone or as a mixture of two or more.

The thickness of the photoabsorption layer including the nanoparticle oxide and the dye is 15 μm or less, and preferably 1 μm to 15. The reason is that the photoabsorption layer has structurally large series resistance to deteriorate conversion efficiency. Accordingly, when the film thickness is set to 15 μm or less, the layer may maintain a function thereof and maintain series resistance at a low level to prevent deterioration of conversion efficiency.

Examples of the electrolyte layer used in the dye-sensitized solar cell may include a liquid electrolyte, an ionic liquid electrolyte, an ionic gel electrolyte, a polymer electrolyte, and a composite thereof. As a representative example, the electrolyte layer includes an electrolyte solution and the photoabsorption layer, or is formed so that the electrolyte solution is dipped in the photoabsorption layer. As the electrolyte solution, for example, an acetonitrile solution of iodine and the like may be used, but the electrolyte solution is not limited thereto, and any electrolyte solution that has a hole-conducting function may be used without limit.

Moreover, the dye-sensitized solar cell may further include a catalyst layer. The catalyst layer is constituted to promote an oxidation and reduction reaction of the dye-sensitized solar cell. As the catalyst layer, platinum, carbon, graphite, carbon nanotubes, carbon black, a p-type semiconductor, a composite thereof, and the like may be used, and is disposed between the electrolyte layer and a counter electrode. It is preferable that the catalyst layer have a fine structure to have an increased surface area. For example, when the catalyst layer is platinum, it is preferable that the catalyst layer be in a platinum black state, and when the catalyst layer is carbon, it is preferable that the catalyst layer be in a porous state. The platinum black state may be formed by treating platinum using an anodic oxidation method, a chloroplatinic acid treatment, and the like. The carbon in the porous state may be formed by a method such as sintering of a carbon particulate, baking of an organic polymer, and the like.

The dye-sensitized solar cell includes the transparent electrode including the graphene sheet having excellent conductivity and flexibility, thus having excellent photo-efficiency and workability.

Examples of the display in which the transparent electrode including the graphene sheet according to one embodiment of the present invention is used may include an electronic paper display, an optoelectronic device (organic or inorganic), a liquid crystal display, and the like. Among the examples, the organic optoelectronic device is an active light-emitting display emitting light when electrons and holes are combined in an organic film if a current flows through a fluorescent or phosphorescent organic compound thin film. In general, the organic optoelectronic device has a structure where an anode is formed on a substrate, and a hole transport layer, an emission layer, an electron transport layer, and a cathode are sequentially formed on the anode. The organic optoelectronic device may further include an electron injection layer and a hole injection layer to facilitate injection of electrons and holes, and additionally a hole blocking layer, a buffer layer, and the like if needed. It is preferable that the anode be a transparent material having excellent conductivity due to the nature thereof. Accordingly, the transparent electrode including the graphene sheet according to one embodiment of the present invention may be availably used.

A typically-used material may be used as a material of the hole transport layer, and polytriphenylamine may be preferably used, but the material is not limited thereto.

A typically-used material may be used as a material of the electron transport layer, and polyoxadiazole may be preferably used, but the material is not limited thereto.

A generally-used fluorescent or phosphorescent light-emitting material may be used as a light-emitting material used in the emission layer without limit. However, the light-emitting material may further include one or more selected from the group consisting of one or more polymer hosts, a mixture host of the polymer host and a low molecular host, the low molecular host, and a non-light-emitting polymer matrix. Herein, any material typically used to form an emission layer for an organic electric field light-emitting device may be used as the polymer host, the low molecular host, and the non-light emitting polymer matrix. Examples of the polymer host include poly(vinylcarbazole), polyfluorene, poly(p-phenylene vinylene), polythiophene, and the like. Examples of the low molecular host include CBP (4,4′-N,N′-dicarbazole-biphenyl), 4,4′-bis[9-(3,6-biphenylcarbazolyl)]-1-1,1′-biphenyl{4,4′-bis[9-(3,6-biphenylcarbazolyl)]-1-1,1′-phenyl}, 9,10-bis[(2′,7′-t-butyl)-9′,9″-spirobifluorenyl anthracene], tetrafluorene, and the like. Examples of the non-light-emitting polymer matrix include polymethyl methacrylate, polystyrene, and the like. However, the examples are not limited thereto. The emission layer may be formed by a vacuum deposit method, a sputtering method, a printing method, a coating method, an Inkjet method, and the like.

According to one embodiment of the present invention, an organic electric field light-emitting device may be manufactured without a particular device or method. The organic electric field light-emitting device may be manufactured according to a method of manufacturing an organic electric field light-emitting device using a common light emitting material.

In addition, the graphene manufactured according to one embodiment of the present invention may be used as an active layer of an electronic device.

The active layer may be used for a solar cell. The solar cell may include at least one active layer between lower and upper electrode layers laminated on a substrate.

Examples of the substrate may be selected from any one of a polyethylene terephthalate substrate, a polyethylene naphthalate substrate, a polyethersulfone substrate, an aromatic polyester substrate, a polyimide substrate, a glass substrate, a quartz substrate, a silicon substrate, a metal substrate, and a gallium arsenide substrate.

Examples of the lower electrode layer may be selected from any one of a graphene sheet, indium tin oxide (ITO), or fluorine tin oxide (FTO).

The electronic device may be a transistor, a sensor, or an organic/inorganic semiconductor device.

A conventional transistor, sensor, and semiconductor device may include a group IV semiconductor heterojunction structure and group III-V and II-VI compound semiconductor heterojunction structures, and restrict electron motion in two dimensions by band gap engineering using the structures to have high electron mobility of about 100 to 1000 cm²/Vs. However, it is proposed that the graphene can have high electron mobility of 10,000 to 100,000 cm²/Vs through theoretical calculation, and thus the graphene may have superb physical and electrical characteristics as compared with a present electronic device when the graphene is used as the active layer of the conventional transistor and the organic/inorganic semiconductor device. In addition, for the sensor, since a fine change according to adsorption/desorption of a molecule in one graphene layer may be sensed, the sensor may have a superb sensing characteristic as compared with the conventional sensor.

The graphene sheet according to one embodiment of the present invention may be applied to a battery.

A specific example of the battery may include a lithium rechargeable battery.

The lithium rechargeable battery may be classified into a lithium ion battery, a lithium ion polymer battery, and a lithium polymer battery according to a kind of used separator and electrolyte. The lithium rechargeable battery may be classified into a cylindrical type, a square type, a coin type, a pouch type, and the like according to a shape, and a bulk type and a thin film type according to a size. Since the structure and the manufacturing method of the batteries are widely known in a related art, a detailed description thereof will be omitted.

The lithium rechargeable battery is constituted by a negative electrode, a positive electrode, a separator disposed between the negative electrode and the positive electrode, an electrolyte incorporated in the negative electrode, the positive electrode, and the separator, a container for the battery, and a sealing member for sealing the container of the battery as main components. The lithium rechargeable battery is constituted by laminating the negative electrode, the positive electrode, and the separator in order, and then receiving the laminated structure into the container of the battery in a spirally wound state.

The positive electrode and the negative electrode may include a current collector, an active material, a binder, and the like. The graphene sheet according to one embodiment of the present invention may be used in the current collector and the like.

For the electrode (positive electrode or negative electrode) using the graphene sheet according to one embodiment of the present invention, a rate characteristic, a life-span characteristic, and the like of the battery may be improved due to the excellent electron mobility.

Needless to say, the graphene sheet according to one embodiment of the present invention is not limited to the aforementioned use, but may be applied to any field and use requiring the characteristics of the graphene sheet.

Hereinafter, specific examples of the present invention will be suggested. However, the examples described below are set forth to specifically illustrate or explain the present invention, but are not to be construed to limit the present invention.

### EXAMPLE

### Manufacturing the Graphene

### Example 1

### Formation of the Graphene on the SiO₂/Si Substrate

In the present example, a liquid carbon source material was used to form the graphene on the SiO₂/Si substrate. The thickness of the SiO₂ layer was 300 nm, and SiO₂ was deposited on the Si substrate by using the thermal growth method.

After the surface of the SiO₂/Si substrate was cleaned, for deposition of the metal thin film, the 100 nm-thick nickel thin film was deposited on the substrate by using the electron beam evaporator. The temperature of the substrate was maintained at 400° C. during the deposition.

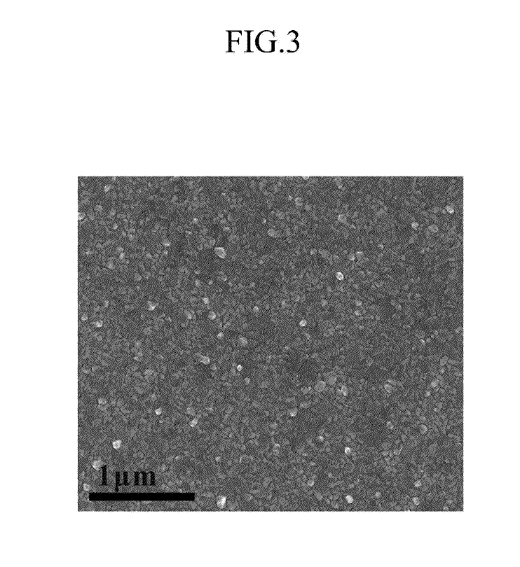

FIG. 3 is a SEM image of the nickel thin film deposited in Example 1.

It can be identified that the polycrystalline nickel thin film was formed, and it can be seen that the grain size was about 50 nm to 150 nm (average 100 nm).

The heat treatment process was performed in order to improve the orientation and to increase the average grain size in the nickel thin film. The heat treatment process was performed in the high-vacuum chamber. The chamber was set in a hydrogen atmosphere by using highly pure hydrogen gas. When the heat treatment was performed at 1000° C. in the appropriate hydrogen atmosphere, the obtained grains were about 10 μm in size and mostly oriented to (111).

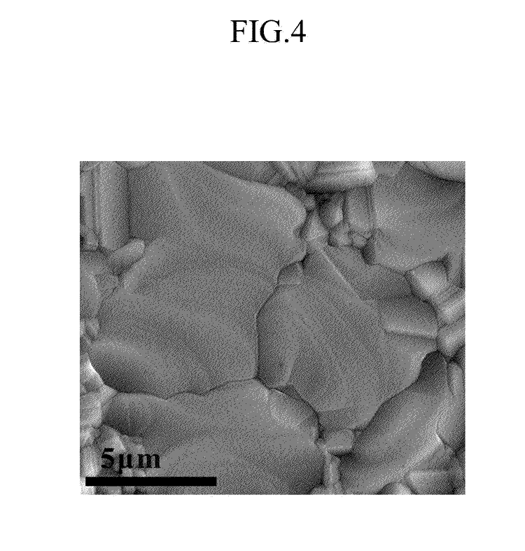

FIG. 4 is a SEM image of the nickel thin film after heat treatment in Example 1, and it can be seen that the grain size is about 1 to 20 μm.

The graphite powder was used as the carbon source material. The graphite powder was purchased from Sigma-Aldrich Co. (Product No. 496596, Batch No. MKBB1941) and had the average particle size of 40 μm or less. After the graphite powder was mixed with ethanol to prepare the slurry, the slurry was put on the substrate on which the nickel thin film was deposited, dried at the appropriate temperature, and fixed using a jig made of a special material.

The specimen manufactured by the aforementioned method was put into the electric furnace and heat-treated so that the carbon source material was spontaneously diffused through the nickel thin film.

The heat treatment temperature was 465° C. The heating time was within 10 minutes, and the heating was performed in an argon atmosphere. The heating was maintained for 5 minutes.

After the diffusion process through the heat treatment was finished, the nickel thin film was etched to reveal the graphene formed at the interface between the nickel thin film and SiO₂. An FeCl₃ aqueous solution was used as the etching solution. The nickel thin film was etched using a 1 FeCl₃ aqueous solution for 30 minutes. As a result, it could be identified that the high quality graphene having a large area was formed on the SiO₂/Si substrate.

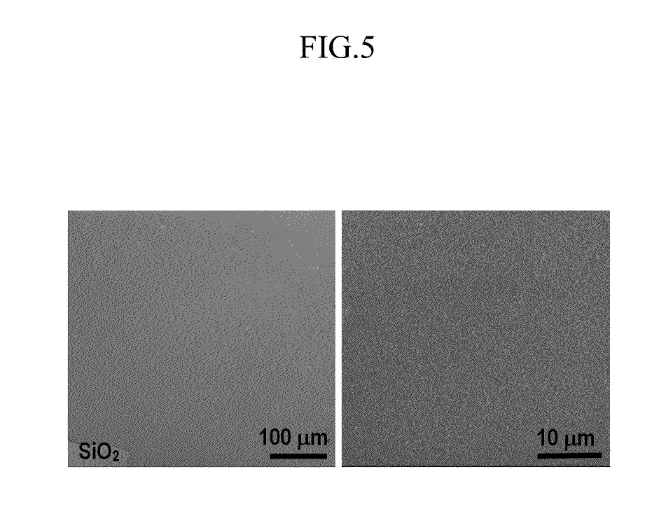

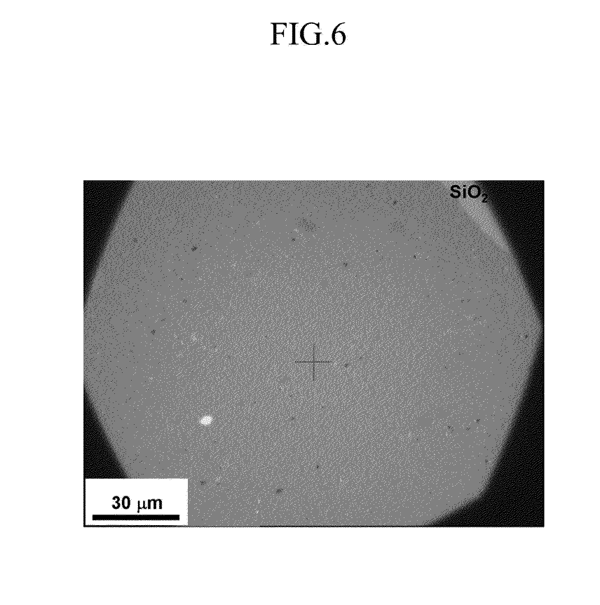

FIG. 5 is a SEM image of the formed graphene sheet, and FIG. 6 is an optical microscope image of the formed graphene sheet. A uniformly formed graphene sheet can be identified.

Further, from FIGS. 5 and 6, it can be seen that since the graphene manufactured in Example 1 is formed at low temperatures, creases formed due to a difference in thermal expansion coefficient of the graphene and the lower substrate do not occur.

That is, it can be seen that the lower sheet is flat. In general, the crease of the graphene sheet is known as one of main factors causing deterioration in physical properties of the graphene sheet.

### Example 2

A graphene sheet was manufactured according to the same method as Example 1, except that the heat treatment temperature was set to 160° C. after putting the carbon source material onto the nickel thin film in Example 1.

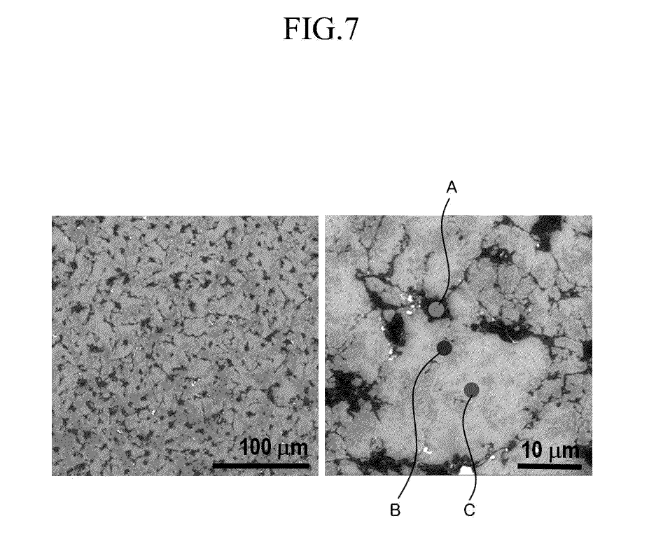

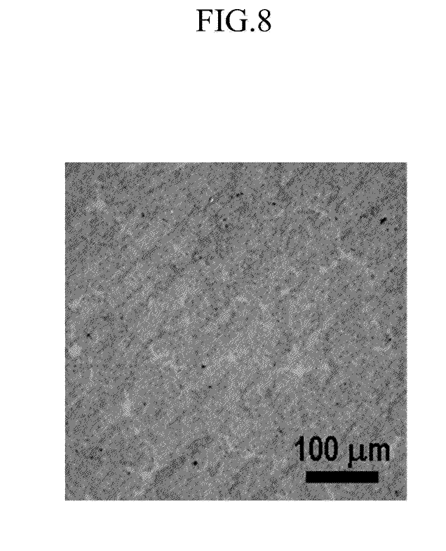

FIG. 7 is a SEM image of the graphene sheet according to Example 2, and FIG. 8 is an optical microscope image of the graphene sheet according to Example 2.

As shown in FIG. 7, it can be identified that the graphene of Example 2 had very large grains with the size ranging from several micrometers to several tens of micrometers. The SEM images show a clear difference in brightness contrast depending on the thickness of the graphene. The lightest image corresponds to the monolayer graphene C, the light image corresponds to the bilayer graphene B, and the darkest image corresponds to the multi-layered graphene A. The multi-layered graphene corresponds to the ridge.

From FIG. 7 it can be seen that the ridge portion is continuously or discontinuously shown in the grain system form of metal. Accordingly, the interval between the ridges may vary depending on the method of forming the cross-section, but the maximum interval between the ridges is approximately identical to the maximum diameter of the grain system of the metal.

For the graphene of Example 2, the maximum interval between the ridges is 1 μm to 50 μm. The ridge is formed of at least three layers of graphene. The height of the ridge varies depending on the growth temperature, the growth time, and the location of the graphene. The thickness of the ridge is reduced away from the center of the ridge and toward the edge thereof.

For the graphene of Example 2, it can be seen that the height of the center of the ridge corresponds to 15 to 30 layers.

Further, from FIGS. 7 and 8, it can be seen that since the graphene sheet manufactured in Example 2 is formed at low temperatures, creases formed due to a difference in thermal expansion coefficient of the graphene sheet and the lower substrate do not occur. In general, the crease of the graphene is one of main factors causing deterioration in physical properties of the graphene.

### Example 3

The graphene was manufactured according to the same method as Example 1, except that heat treatment temperature and the heating maintenance time were set to 60° C. and 10 minutes, respectively, after putting the carbon source material onto the nickel thin film in Example 1.

### Example a

The graphene was manufactured according to the same method as Example 1, except that the carbon source material was put onto the nickel thin film and then maintained at room temperature and the temperature maintenance time was 30 minutes.

### Example 4

### Formation of the Graphene Sheet on Poly[Methyl Methacrylate] (Hereinafter Referred to as “PMMA”)

PMMA in the form of initial powder was mixed with chlorobenzene used as the solvent in a ratio of 1:0.2 (15 wt %) between PMMA and chlorobenzene, and then deposited on the silicon substrate by the sol-gel method.

Specifically, the mixture was subjected to spin coating on the silicon substrate with the size of about 1 cm² at the speed of 3000 RPM for 45 seconds, and remaining impurities and moisture were then removed at the temperature of 70° C. for 15 minutes.

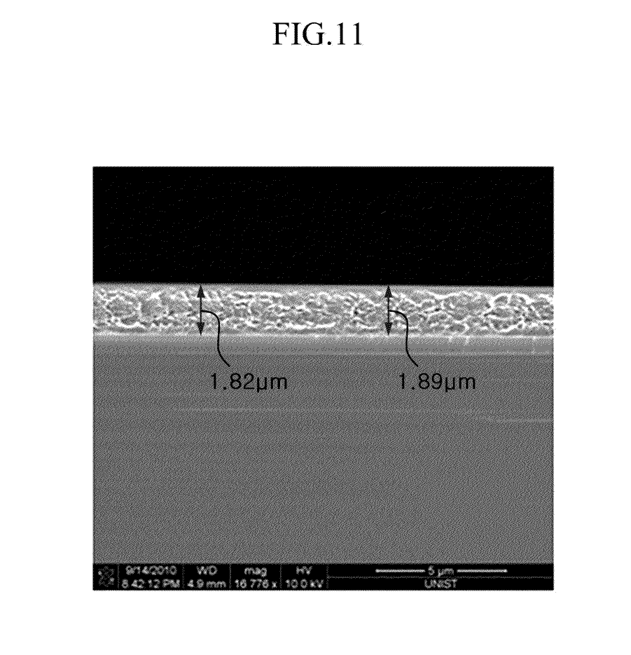

FIG. 11 is a cross-sectional SEM image of a structure where the PMMA film is formed on the silicon substrate.

For deposition of the metal thin film, the nickel thin film having the thickness of 100 nm was deposited using the electron beam evaporator. For the organic material such as PMMA and the like, since the melting point is 200° C. or less, which is very low, the temperature of the substrate was room temperature when nickel was deposited.

The XRD analysis result of the nickel thin film deposited on PMMA at room temperature shows that the polycrystalline thin film is formed of grains having orientations of (111) and (200) at a ratio of about 8 to 1. The average grain size was about 40 nm to 50 nm. Since PMMA is weak against heat, the nickel thin film was not heat-treated after the growth.

Thereafter, the graphite slurry was brought into contact with nickel/PMMA and then fixed by the jig according to the same method as Example 1. The manufactured specimen was put into the electric furnace and heat-treated so that the carbon source material was spontaneously diffused through the nickel thin film.

The heat treatment temperature was 60° C., the heating time was within 5 minutes, and the heating was performed in the argon atmosphere. The heating was maintained for 10 minutes.

After the diffusion process of the carbon source material through the heat treatment was finished, the nickel thin film was etched to reveal the graphene formed at the interface between the nickel thin film and PMMA. The FeCl₃ aqueous solution was used as the etching solution. The nickel thin film was etched using a 1 M FeCl₃ aqueous solution for 30 minutes. As a result, it could be identified that the graphene was formed on the entire area of PMMA.

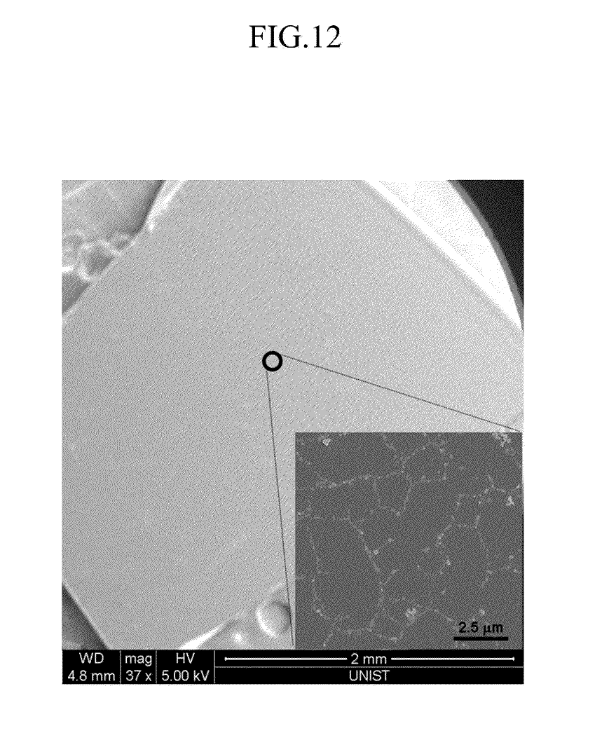

FIG. 12 is a SEM image of the graphene sheet manufactured in Example 4, and it can be identified that the graphene sheet is uniformly formed.

In FIG. 12, it can be identified that the ridge is formed in the grain form of the metal. As described above, since the ridge portion is continuously or discontinuously shown in the grain system form of the metal, the interval between the ridges may vary depending on the method of forming the cross-section, but the maximum interval between the ridges is approximately identical to the maximum diameter of the grain system of metal.

For the graphene of Example 4, the maximum interval between the ridges is 30 nm to 100 nm. The ridge is formed of the graphene of at least three layers. The height of the ridge varies depending on the growth temperature, the growth time, and the location of the graphene. The thickness of the ridge is reduced away from the center of the ridge and toward the edge thereof.

For the graphene of Example 4, it can be seen that the height of the center of the ridge corresponds to 10 to 30 layers.

### Example 5

The graphene was manufactured according to the same method as Example 4, except that the heat treatment temperature was set to 40° C. after putting the carbon source material onto the nickel thin film in Example 4.

### Example 6

The graphene was manufactured according to the same method as Example 4, except that the heat treatment temperature was set to 150° C. after putting the carbon source material onto the nickel thin film in Example 4.

### Example 7

The graphene was manufactured according to the same method as Example 1, except that heat treatment temperature and the heating maintenance time were set to 150° C. and 30 minutes, respectively, after putting the carbon source material onto the nickel thin film in Example 4.

### Example 8

### Formation of the Graphene on Polydimethylsiloxane (Hereinafter Referred to as “PDMS”)

The graphene was manufactured according to the same method as Example 4, except that PDMS was used instead of PMMA in Example 4. However, the process of forming the PDMS thin film is as follows.

Since PDMS having the high density molecular weight (162.38) has high durability, it may just be mixed with the curing agent (PDMS kit B) to cure thick PDMS without the sol-gel method.

PDMS (A) and the curing agent (PDMS kit B) were mixed at a ratio of 10:1 or 7:3 at most to perform crosslinking. Two materials having high viscosity in a gel state were mixed and then post-processed to perform curing. Since PDMS had flexibility, PDMS was attached to the silicon substrate for the post process.

The subsequent process is the same as Example 4 and thus will be omitted.

### Example b

### Formation of the Graphene on the Glass Substrate

The graphene was manufactured according to the same method as Example 4, except that the glass substrate was used instead of PMMA in Example 4.

### Example c

### Formation of the Graphene using the Metal Foil

In Example c, the liquid carbon source material was used to form the graphene on the SiO₂/Si substrate.

The copper foil (or nickel foil) was used as the medium for spontaneous diffusion of the carbon atom. The thickness of the copper foil (or nickel foil) was various and was from 1 μm to 30 μm. In the present example, a purchased copper foil having a thickness of 1 μm was used.

The purchased copper foil was subjected to surface cleaning in the order of acetone cleaning, IPA (isopropyl alcohol) cleaning, DI (deionized) water cleaning, IPA cleaning, and cleaning with nitric acid (HNO₃) having a concentration of 1%.

The heat treatment process was performed in order to improve the orientation and to increase the average grain size in the copper foil. The heat treatment process was performed in the high-vacuum chamber. The chamber was set in a hydrogen atmosphere by using highly pure hydrogen gas. When the heat treatment was performed at 1000° C. in the appropriate hydrogen atmosphere, the obtained grains were about 30 μm in size and mostly oriented to (200).

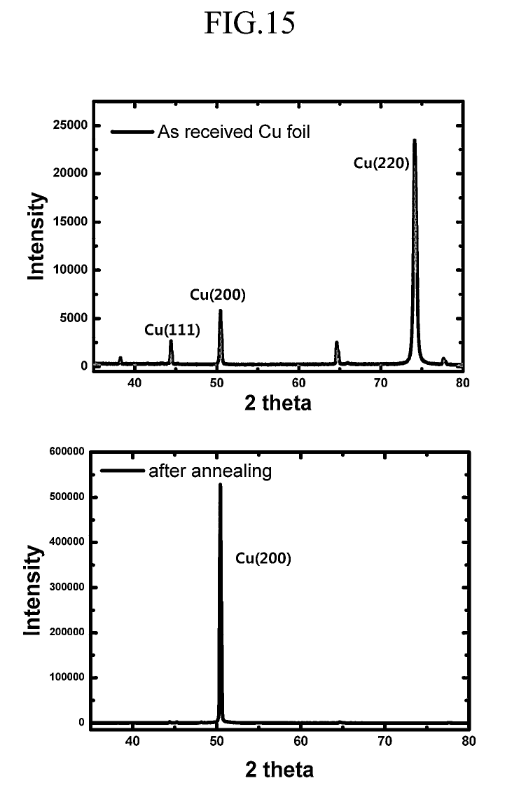

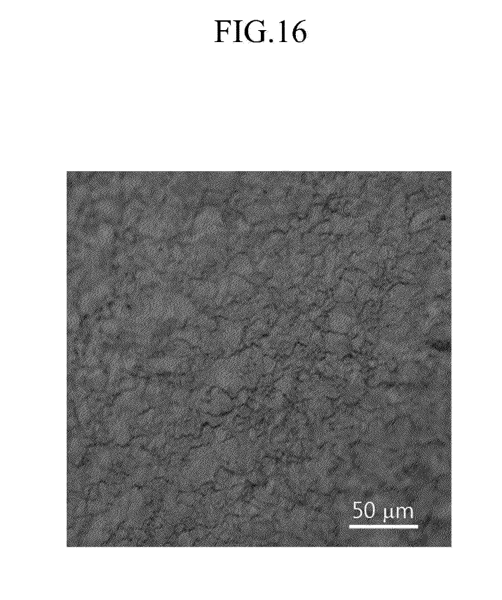

FIG. 15 shows an XRD measurement result of the copper foil before and after heat treatment in Example c, and FIG. 16 is a SEM image of the surface of the copper foil after heat treatment. It can be identified that the polycrystalline copper foil was formed, and it can be seen that the average grain size is about 30 μm.

Thereafter, after the SiO₂/Si substrate was subjected to surface cleaning, the heat-treated copper foil was put on the substrate, and the carbon source material was supplied on the surface of the copper foil. The graphite powder was used as the carbon source material. The graphite powder was purchased from Sigma-Aldrich Co. (Product No. 496596, Batch No. MKBB1941) and had an average particle size of 40 μm or less.

After the graphite powder was mixed with ethanol to prepare the slurry, the slurry was put on the surface of the copper foil and dried at the appropriate temperature, and the structure including the carbon source material/copper foil/substrate was fixed using a jig made of a special material.

The specimen manufactured by the aforementioned method was put into the electric furnace and heat-treated so that the carbon source material was spontaneously diffused through the copper foil.

The heat treatment temperature was 160° C. The heating time was within 10 minutes, and the heating was performed in the argon atmosphere. The heating was maintained for 60 minutes.

After the diffusion process through the heat treatment was finished, the jig was removed, and the carbon source material on the copper foil was removed. As a result, it could be identified that graphene having a large area was formed on the bottom of the copper foil, that is, the surface of the copper foil facing the substrate. This is a result regardless of the process conditions and the kind and the thickness of the metal foil.

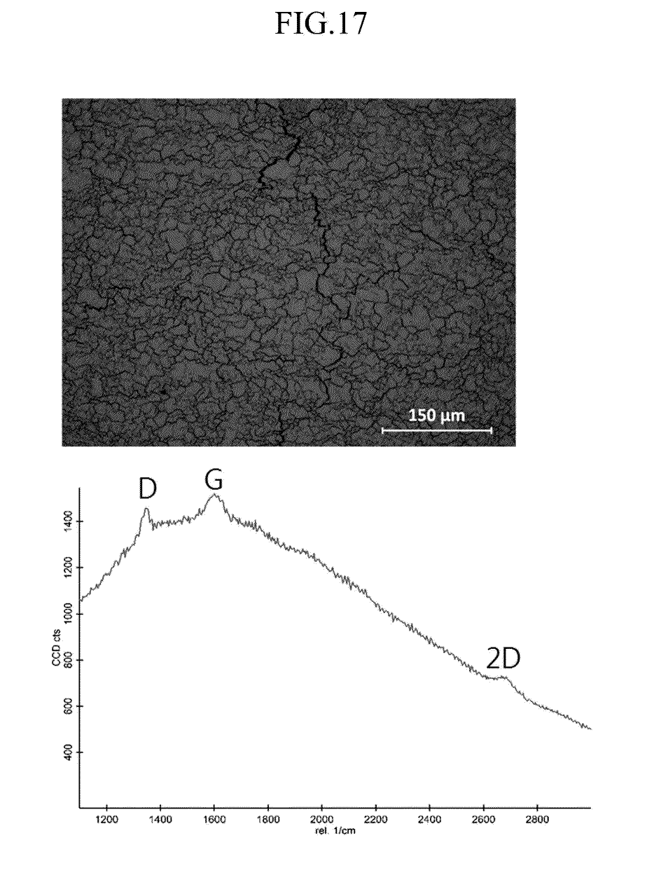

FIG. 17 shows an optical microscope image and a Raman measurement result of the graphene sheet formed on the bottom of the copper foil. In FIG. 17, when the graphene is measured on the copper foil, the intensity of the background peak is excessively high due to the copper foil. Accordingly, for more detailed observation, the graphene formed on the copper foil was transferred to the SiO₂/Si substrate.

A generally known PMMA process was used for the transfer process. First, after PMMA was formed on a graphene/copper foil hetero-structure by using the spin-coating method, the copper foil was etched with the FeCl₃ aqueous solution to form the PMMA/graphene hetero-structure.

Thereafter, the PMMA/grapheme was put on the SiO₂/Si substrate, and PMMA was etched with the acetone solution to finally transfer the graphene on the SiO₂/Si substrate.

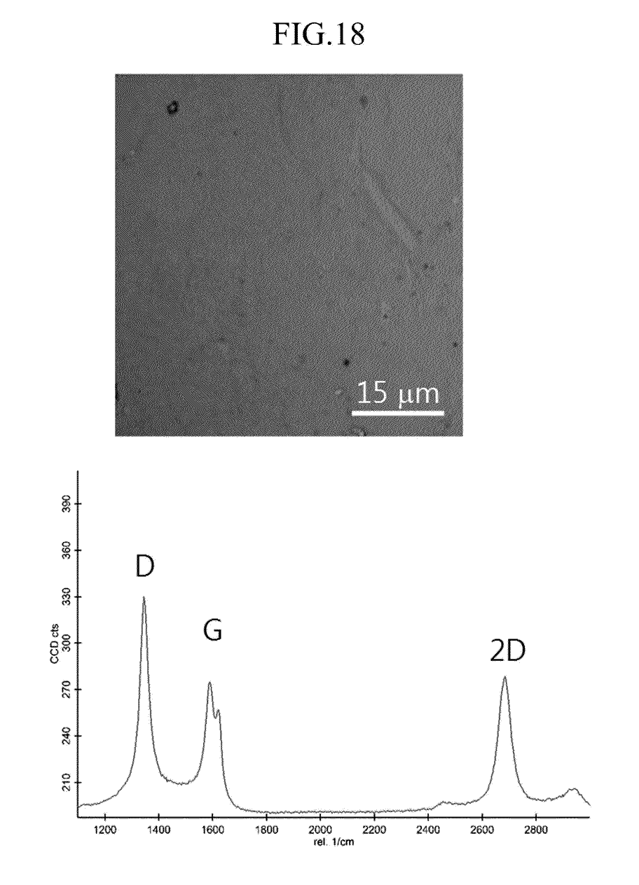

FIG. 18 shows an optical microscope image and a Raman measurement result of the graphene sheet transferred on the SiO₂/Si substrate, and it can be identified that the grapheme sheet is uniformly formed therethrough.

### EXPERIMENTAL EXAMPLE

### Characteristic Evaluation of the Graphene

Evaluation of the Electrical Characteristic

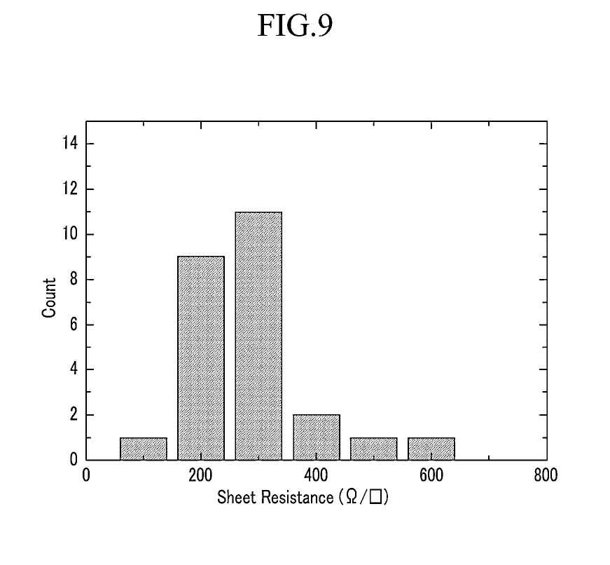

The graphene according to Example 3 was patterned to be 100 μm×100 μm and then measured through a van der Pauw method. As a result, the graphene was identified to have sheet resistance of about 274 Ω/square. The results are shown in FIG. 9.

Compared with a reported value (1000 Ω/square or less) of the graphene formed at high temperatures by a CVD method, the graphene manufactured in Example 3 had remarkably small sheet resistance, and thus the electrical characteristic of the graphene could be identified to be excellent.

In other words, in the method of manufacturing graphene according to one embodiment of the present invention, graphene having a large area may be grown at a temperature of 300° C. or lower, in particular, at a temperature of approximately 40° C., which is close to room temperature, and may be directly grown on an inorganic and organic material substrate, rather than a metal substrate, without transferring. Accordingly, the method has a merit in that the grown graphene has excellent characteristics as compared with the graphene grown by a CVD method.

Evaluation of the Optical Characteristic

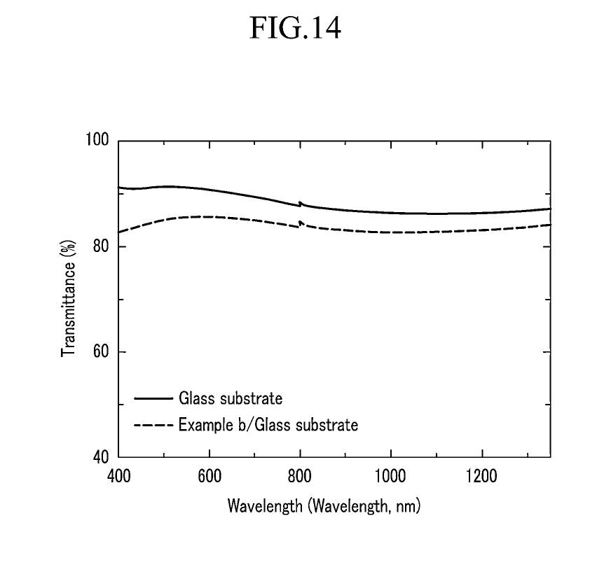

The transmittance of the graphene according to Example b was evaluated in the visible ray range using the UV-VIS method. From FIG. 14, it can be seen that the graphene grown on the glass substrate has high transmittance of 80% or more over the entire visible ray range, and a transmittance reduction due to the graphene is about 2 to 7% as compared with the transmittance of the glass substrate itself.

On the other hand, the transmittance reduction due to the graphene monolayer is known to be 2.3%. Accordingly, it can be indirectly identified that the thickness of the graphene used in the present evaluation corresponds to three layers or less.

The identified transmittance reduction value is much higher than that of the graphene manufactured by a chemical vapor deposition method, which shows the excellent optical characteristic of the graphene manufactured in Example b.

Evaluation of the Heat Treatment Condition to Increase the Grain Size of the Metal Thin Film

Through the heat treatment of the metal thin film, orientation of the metal thin film may be adjusted and the grain size of the metal thin film may be increased to increase the grain size of the formed grapheme, thereby improving graphene characteristics.

In this case, for the heat treatment, a high temperature range where a subject substrate is not damaged should be selected. Ni/SiO₂/Si used in Example 1 was heat-treated at 1000° C. in the high vacuum (10⁻⁹ Torr) chamber to obtain the nickel thin film including grains having the average size of about 5 μm with (111) orientation.

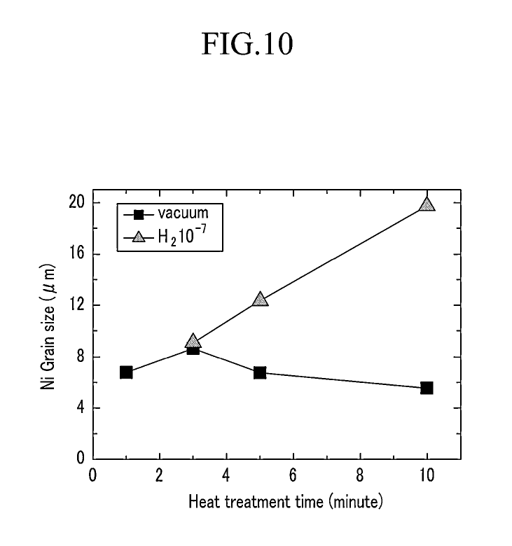

FIG. 10 is a graph showing a change in average grain size of the nickel thin film depending on the heat treatment time in the hydrogen atmosphere.

When hydrogen flows during the heat treatment, the grain size of nickel is increased by several times. Accordingly, when the heat treatment is performed for 10 minutes while hydrogen flows at 10⁻⁷ Torr, a nickel thin film including grains having the average size of about 20 μm with (111) orientation may be obtained.

However, when hydrogen flows in an appropriate amount or more during the heat treatment, the grain size of the nickel thin film may be increased, but when the carbon source material is subsequently diffused into the nickel thin film, the carbon source material may react with hydrogen to be removed, thus forming no graphene on the SiO₂/Si side.

Thickness Measurement of the Graphene According to Example 4 Through an Atomic Force Microscope (AFM)

The graphene manufactured in Example 4 was the graphene having the large area grown on the organic material substrate. Accordingly, there was a difficulty in measurement, and thus the grown graphene was transferred on the SiO₂/Si substrate.

After transferring, the thickness of the graphene was measured through an atomic force microscope.

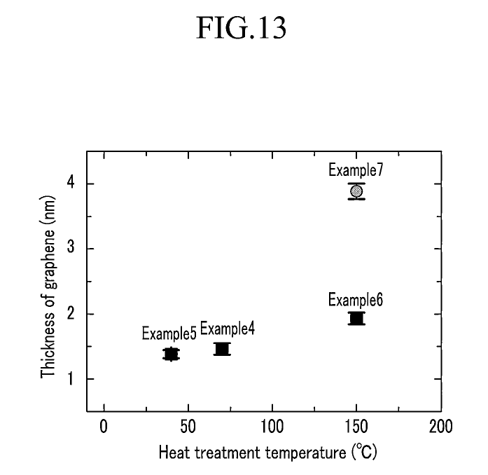

FIG. 13 shows a measurement result of the thicknesses of the graphenes according to Examples 4 to 7. The measured thickness of the graphene was about 1 nm to 2 nm, and thus it could be identified that most of the graphenes were very thin having a thickness of 1 to 3 layers.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting in any way.

<Description of Symbols>

| | | |
|---|---|---|
| 100: graphene sheet | 101: lower sheet | 102: ridge |

What is claimed is:

1. A graphene sheet comprising:
a lower sheet including 1 to 20 layers of graphene; and
a ridge formed on the lower sheet and including more layers of the graphene compared with the lower sheet,
wherein the ridge has a shape of a grain boundary of a metal.

2. The graphene sheet of claim 1, wherein the ridge includes 3 to 50 layers of the graphene.

3. The graphene sheet of claim 1, wherein a size of a metal grain is 10 nm to 10 mm.

4. The graphene sheet of claim 1, wherein a size of a metal grain is 10 nm to 500 μm.

5. The graphene sheet of claim 1, wherein a size of a metal grain is 50 nm to 10 μm.

6. The graphene sheet of claim 1, wherein the lower sheet is a flat sheet.

7. The graphene sheet of claim 1, wherein the metal includes Ni, Co, Fe, Pt, Au, Al, Cr, Cu, Mg, Mn, Mo, Rh, Si, Ta, Ti, W, U, V, Zr, Zn, Sr, Y, Nb, Tc, Ru, Pd, Ag, Cd, In, Re, Os, Ir, Pb, or a combination thereof.

8. The graphene sheet of claim 1, wherein light transmittance of the graphene sheet is 60% or more.

9. The graphene sheet of claim 1, wherein light transmittance of the graphene sheet is 80% or more.

10. The graphene sheet of claim 1, wherein sheet resistance of the graphene sheet is 2000 Ω/square or less.

11. The graphene sheet of claim 1, wherein sheet resistance of the graphene sheet is 274 Ω/square or less.

12. The graphene sheet of claim 1, wherein sheet resistance of the graphene sheet is 100 Ω/square or less.

13. A transparent electrode comprising the graphene sheet according to claim 1.

14. An active layer comprising the graphene sheet according to claim 1.

15. A display comprising the transparent electrode according to claim 13.

16. An electronic device comprising the active layer according to claim 14.

17. The display of claim 15, wherein the display is a liquid crystal display, an electronic paper display, or an optoelectronic device.

18. The electronic device of claim 16, wherein the electronic device is a transistor, a sensor, or an organic/inorganic semiconductor device.

19. An optoelectronic device comprising:
an anode;
a hole transport layer;
an emission layer;
an electron transport layer; and
a cathode,
wherein the anode is the transparent electrode according to claim 13.

20. A battery comprising the transparent electrode according to claim 13.
